(19) United States
(12) Patent Application Publication
(10) Pub. No.: US 2007/0125415 A1
(43) Pub. Date: Jun. 7, 2007

(54) Light capture with patterned solar cell bus wires

(75) Inventor: Emanuel M. Sachs, Newton, MA (US)

Correspondence Address: STEVEN J WEISSBURG, 238 MAIN STREET, SUITE 303, CAMBRIDGE, MA, 02142, US

(73) Assignee: Massachusetts Institute of Technology, Cambridge, MA (US)

(21) Appl. No.: 11/588,183

(22) Filed: Oct. 26, 2006

Related U.S. Application Data
(60) Provisional application No. 60/742,486, filed on Dec. 5, 2005.

(51) Int. Cl. H01L 35/30

(52) U.S. Cl. 136/205

(57) ABSTRACT

Crystalline silicon PV modules typically use tinned flat copper wire to increase the conductivity of a bus bar metallization and to interconnect to adjacent cells. Such a flat bus wire may be patterned with shallow v-shaped grooves using metal forming techniques, such as rolling, stamping and drawing. The grooves are designed so that incident light is reflected up toward the glass superstrate of the module at an internal interface angle that is large enough (typically greater than about 40°) so that the light undergoes total internal reflection at the glass-air interface and is reflected onto the solar cell. A photocurrent resulting from the normal impingement of light on a proto-type of such a patterned bus bar is at least 70% of the photocurrent resulting from the direct impingement on active cell area of the same light source. A typical face angle of about 60° may provide TIR for at least 50% of the light that strikes the bus wire as omni-directional illumination. Substantially all of the light that strikes the cover external surface at any external interface angle less than about 30 degrees relative to the perpendicular to the cover surface can experience TIR. Improvement in module efficiency comes at very small incremental cost and adds no extra steps in cell or module fabrication. Typical face size is between 5 and 150 microns, with spacing between crests of about twice that range. Grooves can be lengthwise along the conductor, or at an angle, or angles. Rather than grooves, inclined faces can form pyramids, or other shapes. The surface may beneficially be specular.

### RELATED DOCUMENTS

The benefit of U.S. Provisional application No. 60/742,486, filed on Dec. 5, 2005, is hereby claimed.

### SUMMARY

A more detailed partial summary is provided below, preceding the claims. Crystalline silicon PV modules typically use tinned flat copper wire to increase the conductivity of a bus bar metallization and to interconnect to adjacent cells. Such a flat bus wire may be patterned with shallow v-shaped grooves using metal forming techniques, such as rolling, stamping and drawing. The grooves are designed so that incident light is reflected up toward the glass superstrate of the module at an internal interface angle that is large enough (typically greater than about 40°) so that the light undergoes total internal reflection at the glass-air interface and is reflected onto the solar cell. A photocurrent resulting from the normal impingement of light on a proto-type of such a patterned bus bar is at least 70% of the photocurrent resulting from the direct impingement on active cell area of the same light source. A typical face angle of about 60° may provide TIR for at least 50% of the light that strikes the bus wire as omnidirectional illumination. Substantially all of the light that strikes the cover external surface at any external interface angle less than about 30 degrees relative to the perpendicular to the cover surface can experience TIR. Improvement in module efficiency comes at very small incremental cost and adds no extra steps in cell or module fabrication. Typical face size is between 5 and 150 microns, with spacing between crests of about twice that range. Grooves can be lengthwise along the conductor, or at an angle, or angles. Rather than grooves, inclined faces can form pyramids, or other shapes. The surface may beneficially be specular.

The inventions disclosed herein will be understood with regard to the following description, appended claims and accompanying drawings, where:

### BRIEF DESCRIPTION OF THE FIGURES OF THE DRAWING

FIG. 1 is a schematic representation of a solar cell, including an absorber, bus wires with a continuous pattern on the wires, gridlines and connecting portions of the bus wires, with one bus wire shown detached to reveal a bus bar beneath;

FIG. 2 is a schematic representation showing two solar cells strung together to form a short string;

FIG. 3 is a schematic representation in cross-sectional view of a portion of FIG. 2, along lines A-A, also illustrating light capture from a patterned bus wire;

FIGS. 4A and 4B are schematic representations illustrating a class of limiting case beyond which Total Internal Reflection (TIR) will not take place and light will escape from a module, shown in two parts, FIG. 4A (TIR), where both the incident ray and the normal to the face struck by the ray are on the same side of the normal to the external cover surface, and FIG. 4B (light escaping);

FIG. 5 shows, schematically, a set of light rays striking a patterned bus wire, which rays lie in a plane that is perpendicular to the dimension of elongation of the grooves of the bus wire;

FIG. 6 shows, schematically, a set of light rays striking a patterned bus wire, which rays lie in a plane that is parallel to the dimension of elongation of the grooves of the bus wire;

FIG. 7 shows a module which light from the sun strikes;

FIGS. 8A, 8B, 8C, 8D and 8E are schematic representations of another class of limiting case where light, where the incident ray and the normal to the face struck by the ray are on opposite sides of the normal to the external cover surface, with TIR occurring in the cases shown in FIGS. 8A, 8B and 8D and with light escaping in FIGS. 8C and 8E;

FIG. 9 is schematic representation of a cross-sectional cut through a bus wire, also along the lines A-A of FIG. 2;

FIG. 10 is a schematic representation of a test cell structure for confirming the effectiveness of inventions disclosed herein;

FIG. 11 is a schematic representation of laser light hitting a bus wire and being re-directed by virtue of TIR to the test collecting cell surface shown in FIG. 10;

FIG. 12 is a graphical representation showing recapture ratio as a function of angle of incidence, for a test cell as shown in FIG. 10;

FIG. 13 is a graphical representation of reflection intensity of a patterned bus wire as a function of angle;

FIG. 14 shows schematically, a bus wire of an invention hereof, having a patterned region and an un-patterned region;

FIG. 15 shows schematically, a mandrel with grooves around its periphery for patterning a bus wire;

FIG. 16 shows schematically, a mandrel with grooves around a portion of its periphery, with another portion un-grooved, to form a bus wire having grooves that are interrupted by flat sections;

FIG. 17 shows schematically, a bus wire having grooves with faces that are not planar, and FIG. 17A shows a cross-section thereof at lines A-A;

FIG. 18 shows schematically, a bus wire having v-shaped grooves with different angles, and FIG. 18A shows a cross-sectional view thereof at lines A-A;

FIG. 19 shows schematically, a bus wire having grooves imposed upon a surface that is not flat and FIG. 19A shows a cross-sectional view thereof at lines A-A;

FIG. 20 shows schematically, a bus wire with grooves inclined at an angle of 45° to the long axis of the bus wire;

FIG. 21 shows schematically, chevron shaped bus wire grooves, with their apexes aligned along a long axis of the bus wire;

FIG. 22 shows schematically, a pattern of roughly pyramidal shaped protrusions from a bus wire and corresponding depressions there between; and

FIG. 23 shows, schematically, a cone, having a half angle C, within which light rays striking a patterned bus wire, will reflect to a cover and undergo TIR.

### DETAILED DESCRIPTION

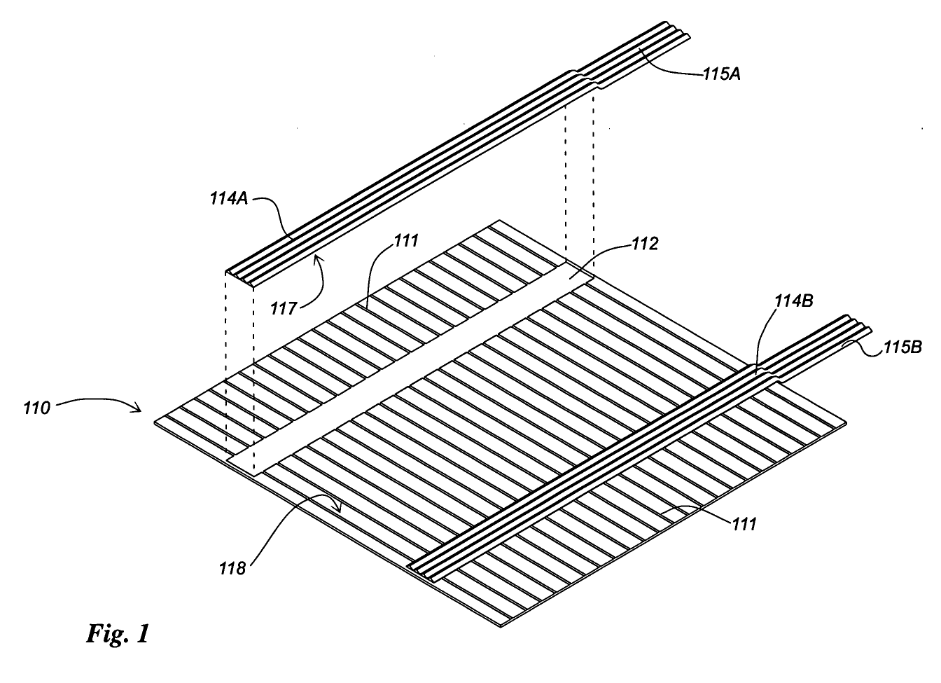

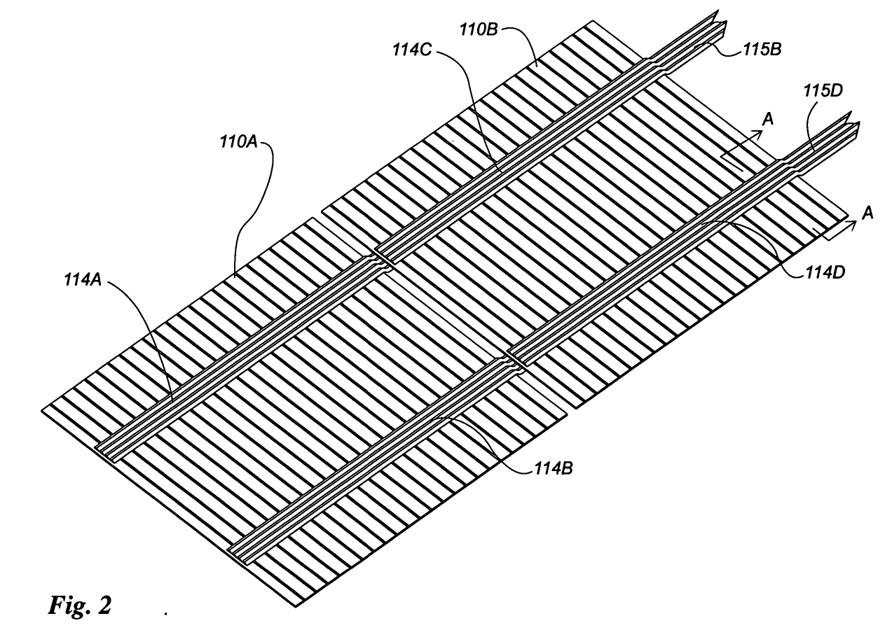

A silicon solar cell photovoltaic device 110 is shown schematically in FIG. 1. A metallization pattern is applied to the solar cell absorber, most commonly by screen printing of silver inks, but alternatively by other means known in the art. This pattern consists of fine gridlines (also known as fingers) 111 and bus bars 112, which collect the current from the fingers 111. In an independent process, bus wires 114A, 114B are then adhered to the bus bar portion 112 of the cell metallization, usually by soldering. In FIG. 1 bus wire 114A is shown as adhered to the metallization, while bus wire 114B is shown in an exploded view so that the metallization bus bar 112 can be seen. The bus wire is typically tinned copper flat wire. These bus wires greatly increase the conductivity of the bus bar and also serve as the mechanism for interconnecting cells with adjacent cells in a series connection. The top contact of one cell is connected to the back contact (not shown) of another, as shown schematically in FIG. 2 by the bus wire 114A, extending beyond an edge of one cell 110A, and bending down and under an adjacent cell 110B.

The bus wires shown in FIG. 1 are not typical. They are part of an invention hereof. However, their placement relative to the other parts of a cell is relatively typical, and the typical placement can be understood from this figure. Bus wire may also be called bus ribbon, interconnect wire and tabbing wire (the latter two terms deriving from the function of connecting adjacent cells). Typically herein, the term bus wire will be used.

Conventional bus wires are simple and inexpensive. They form the basis for part of the automation of module assembly and afford a high degree of immunity to cell cracking. There are, however, drawbacks. Most prominent is the issue of shaded area, which ranges from 3-6%. Increasing the number or width of bus wires decreases the amount of current that can be collected from a cell absorber. In the language of solar cell characterization, the short circuit current (I_{SC}) is decreased, due to increased shading. This negative impact on cell efficiency is partly balanced by reducing the series resistance of the metallization and therefore reducing the voltage drop in the metallization. This results in a higher cell voltage at a given operating current. In the language of solar cell characterization, the fill factor (FF) is increased Thus, there is a design tradeoff, resulting in an optimal number and width of bus wires for a given cell design. This design tradeoff becomes more severe as the size of cells increases, because the longer lengths of bus wire required to traverse the cell greatly increase the voltage drop in the bus wire. Further, the movement to thinner cells will place further limitation on bus wire design, due to issues of thermal expansion mismatch. This constraint, among others, makes it unlikely that the thickness of bus wires can be increased.

In sum, the photovoltaic industry trends of larger cells and thinner cells restrict the design space available and will result in greater percentage losses of power due to the presence of bus wires. A purpose of inventions described herein is to open this design space by substantially reducing the severity of the tradeoff between I_{sc} and FF in bus wire design and thereby to increase total module power output.

Inventions disclosed herein typically involve using a flat conductor, patterning that, and then applying it to a previously metallized substrate, which may be flat or otherwise. The conductor of inventions hereof is free-standing as an already formed element, separate from the absorber before the conductor is contacted to the absorber.

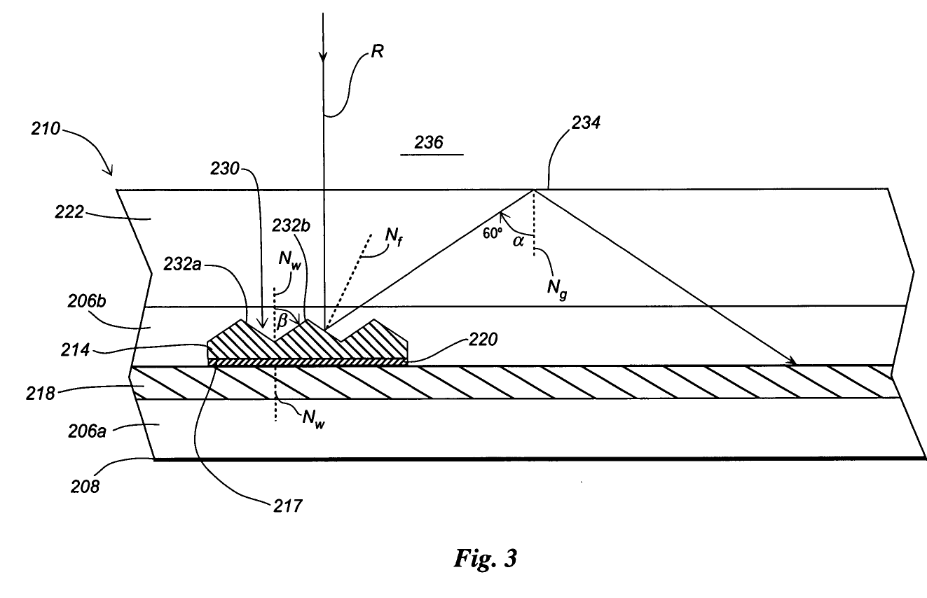

Inventions described herein are directed at capturing a substantial portion of the light which is reflected from the bus wire, away from the cell, by reflecting it back onto the absorber of the cell. This is illustrated schematically in FIG. 3, which is a cross-section through an entire module 110, including backskin 208, encapsulant 206a, absorber 218, metallization 220, bus wire 214, encapsulant 206b and top glass 222. The bus wire 214 is patterned with shallow grooves 230, which have faces 232a, 232b, which are typically inclined at a wire face angle β, shown at +/−60° from a line N_{g}, normal (perpendicular) to the glass cover external surface, which is typically also parallel to the line N_{W}, which is normal to a plane defined by the base or back surface 217 of the bus wire. Because this is illustrated more clearly with reference to the wire base normal N_{W}, that is how it is shown in the figures. However, the ultimately important relationship for an assembled device, is the angle relative to the line N_{g} perpendicular to the external surface of the glass cover. Typically, the back surface of the bus wire will be substantially flat, and is referred to herein at times also as a base surface, or an obverse surface. However, the surface need not be flat, as long as it can be adequately secured to the absorber, and also as long as adequate electrical contact to the grid lines and bus bar (if present) can be established. In any case, whether the base surface is flat or not, there will be a plane defined by the base surface, which is the plane at which contact is made between the base surface and the elements to which it is attached.

Light (ray R) incident on the bus wire 214 is reflected up toward the interface 234 between the glass cover 222 and an external environment 236. The environment 236 can be an atmosphere, or vacuum, if used in outer space. The light that internally reflects within the cover and encapsulant of the solar cell, strikes the interface at an internal interface angle α relative to the normal N_{g}, perpendicular to the cover external surface, which is large enough, that is far enough away from the normal N_{g}, to result in a total internal reflection (TIR) from the glass/atmosphere interface 234. The light is then reflected down on the absorber 218. For glass with an index of refraction of 1.5, the internal interface angle α at the glass-environment interface must exceed a minimum of approximately 42°.

When a wire is fabricated, it is designed with an obverse surface that is shaped in anticipation of how it will be applied to an absorber, and how a cover will be applied to the absorber. Typically, the base surface is planar, the absorber surface is planar, and the cover external and internal surfaces are planar, and all are assembled to be parallel each other. However, this need not be the case, and they may be inclined relative to each other. The designer will then need to take these inclinations into account, in light of the desired external interface angle to insure TIR. As used herein, the face angle means the angle β, discussed above, measured from the line that is perpendicular to both the cover external surface and the wire base surface, if they are parallel. If a wire is being discussed, without a cover applied, then the face angle may be measured from the line that is perpendicular to the wire base surface.

The formula below relates the minimum internal interface angle (in radians) of incidence αₘᵢₙ to the index of refraction, n, of the glass. This formula is derived from Snell's law of refraction where the air is taken to have an index of refraction of 1.
αₘᵢₙ=sin⁻(1/n). (Eq. 1).

In the case of a ray R directed at normal incidence onto a bus wire 214 that is patterned with grooves 230 having a face angle β of 60°, this internal interface angle of incidence α is 60° (because the incoming ray R is normal to the glass), which is adequate for TIR over a minimum internal interface angle αₘᵢₙ by a wide margin (of about 18°). The light trapping is accomplished by the system comprising the absorber 218, the glass superstrate 222 and the encapsulant layer 206b between absorber 218 and glass 222. (FIG. 3 shows an idealized situation where 100% of the light energy of ray R passes through the interface 234 into the glass. In reality, even with low absorbing glass used for solar module cover manufacture, about 4% of the incident ray R is reflected from the interface to the environment 236 and does not enter the glass 222.)

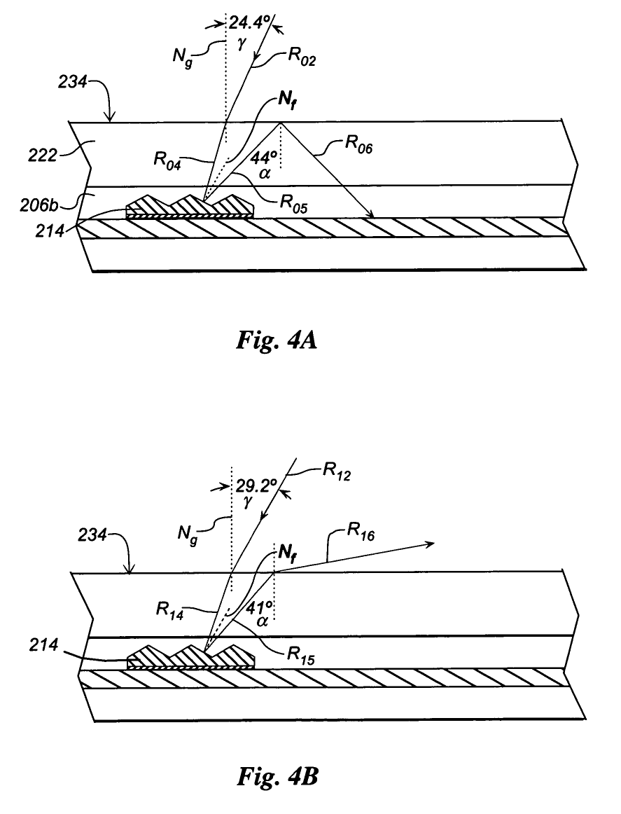

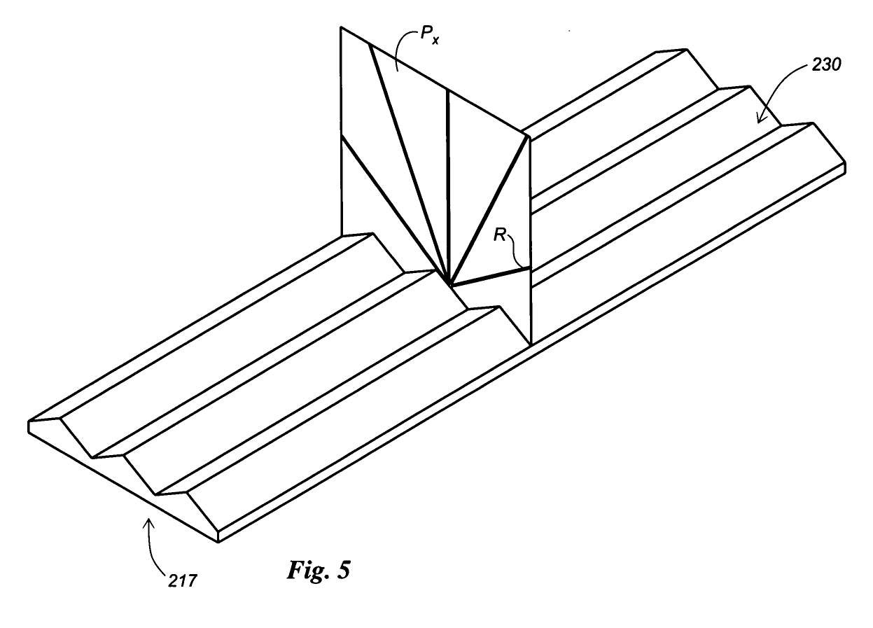

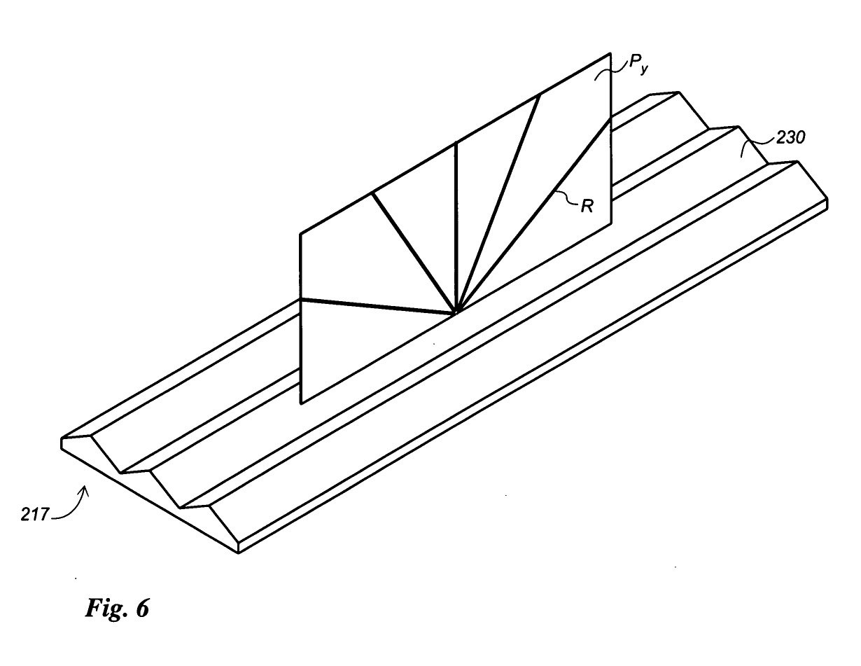

Implementation of this concept traps incoming light over a large range of external interface angles γ (FIG. 4A) relative to a normal line N_{g}, perpendicular to the glass/environment interface (the external cover surface). The discussion below first examines incoming rays R that lie in a plane Pₓ perpendicular to the v-grooves 230 of the bus bar 214, as shown in FIG. 5, and then also incoming rays R that lie in a plane P_{y} parallel to the v-grooves, as shown in FIG. 6. Typically, in any situation, rays will arrive with components lying in both plane Pₓ and plane P_{y} over the course of daily, seasonal and weather related changes.

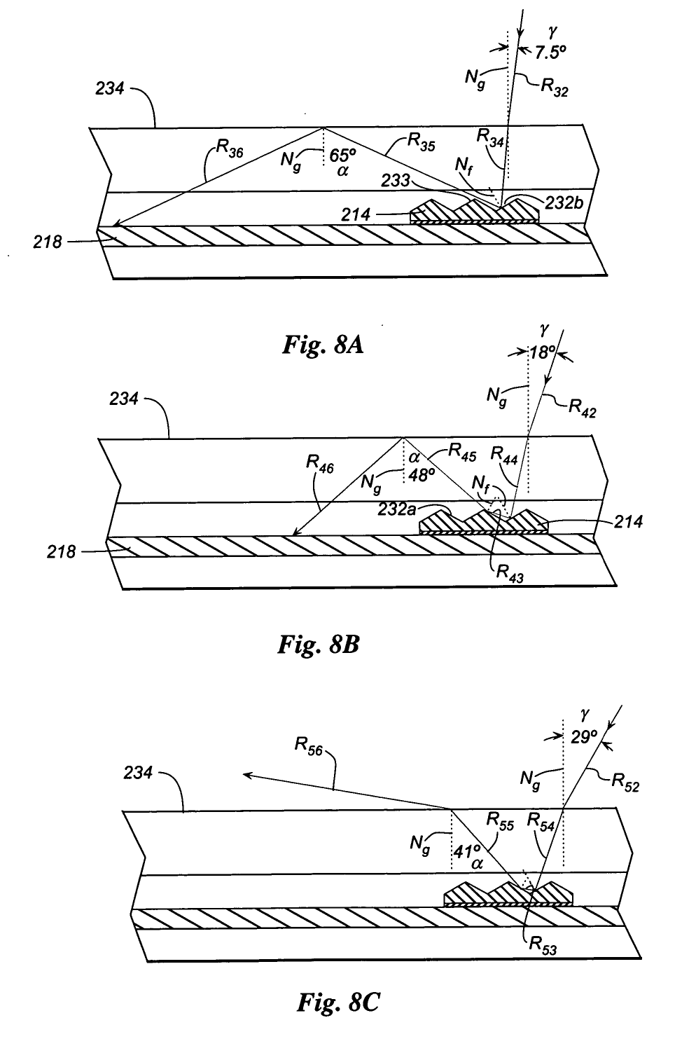

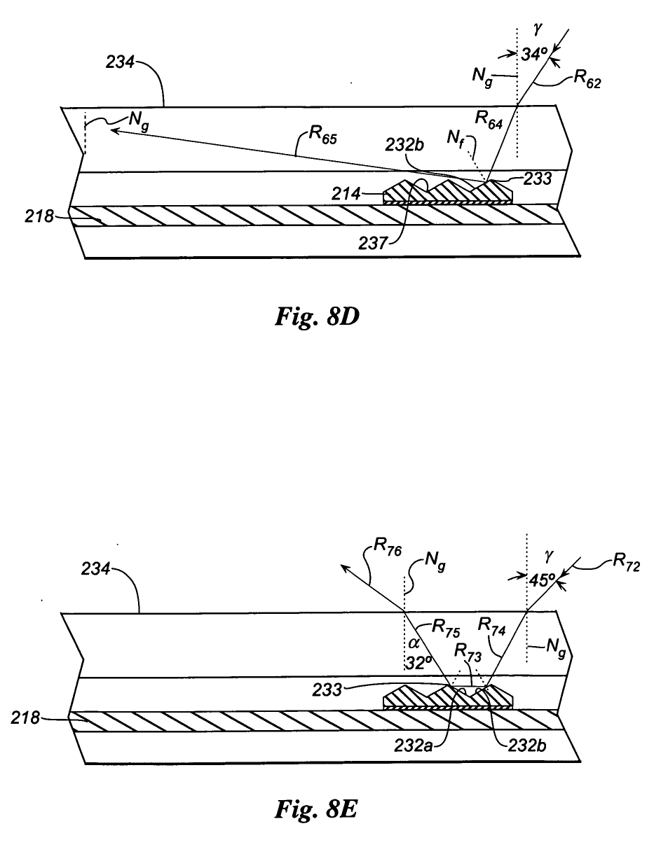

The allowable range of external interface angles γ of a component of incoming rays lying in a plane perpendicular to the v-grooves can be understood with reference to FIGS. 4A and 4B and FIGS. 8A-8E. FIGS. 4A and 4B show cases where the incident external ray and the normal (shown dashed) to the face N_{f} (the typically flat surface from a crest to an adjacent trough) that the ray hits are both inclined in the same direction (in this case, clockwise, as shown) relative to the normal N_{g} to the glass. FIGS. 8A-8E show another case, where the incident ray R and the normal N_{f} to the face that the ray hits, are inclined in opposite directions relative to the normal N_{g} to the glass. All figures are drawn in cross-section, with the bus wire being of the type shown in FIG. 3, with face angles at +/−60° relative to a normal to the wire back 217 (and typically also, the glass). The glass and the encapsulant are taken to have an index of refraction of 1.5.

Ray R₀₂ in FIG. 4A does result in TIR of the ray after reflection from the patterned bus wire 214, even though ray R₀₂ is incident on the glass 222 at an off-normal external interface angle γ. Upon entering the glass 222, the ray, now designated ray R₀₄ changes angle due to refraction at the air-glass interface and moves closer to the normal N_{g}. The refraction contributes to a significant increase in the range of external interface angles γ over which light can be accepted into the module and trapped by TIR. (Also, there is no change of angle shown at the interface between the glass 222 and the encapsulant 206b. This is because the glass and encapsulant are deliberately matched in index of refraction.)

With an incoming ray R₀₂ inclined at γ=24.4° as shown, refracting and then as ray R₀₄ striking the face 232a shown in FIG. 4A, having a face angle β=60°, the ray reflects as R₀₅ and strikes the glass/environment interface at an internal interface angle α=44°, which is greater than αₘᵢₙ of 42°, and so the ray reflects back to the absorber surface 218 as R₀₆, where it is absorbed, as desired.

For incident rays having different external interface angles of incidence with respect to the normal N_{g}, as the external interface angle γ continues to increase, there eventually is an external interface angle γₘₐₓ where TIR does not take place, and the ray escapes back out from the surface 234 of the glass.

As shown in FIG. 4B, the ray R12 strikes the glass surface 234 at an external interface angle γ=29.2°. It refracts and as ray R₁₄ strikes the face of the bus wire 214 so that it reflects as ray R₁₅, which strikes the glass to environment interface 234 at an internal interface angle α=41°, which is less than αₘᵢₙ. Thus, the ray escapes as R₁₆ and is not absorbed. For the specific case of a bus wire with faces at β=+/−60 degrees and glass/encapsulant with an index of refraction of 1.5, the maximum external interface angle γₘₐₓ relative to the normal of the glass at which a ray can be incident and still undergo TIR, is approximately 27.6°. This maximum angle depends only on the face angle β and the indices of refraction of the media, not the thicknesses of the media.

Thus, the range of useful face angles β can be evaluated by considering the range of indices of refraction likely to be encountered in glasses and other materials used to cover solar cell assemblies. This range of indices is rather small, near 1.5. Thus, bus wires having face angles β ranging between +/−50° to +/−70° will accommodate most materials likely to be encountered, with angles ranging between +/−55° to +/−65° satisfying the bulk thereof.

FIGS. 8A-8E show a different class of cases where the incident rays R and the normal N_{f} to the faces that the rays hit are inclined in opposite directions relative to the normal N_{g} to the glass, (with the incoming rays inclined clockwise, and the normal to the face inclined counter-clockwise as shown in these examples). In these cases, whether or not an incident ray undergoes TIR depends both on the external interface angle γ of incidence and the location on the face at which the ray is incident. FIGS. 8A, 8B, 8C show cases where rays are incident near the bottom of the faces, and 8B and 8E near the top of the faces.

In FIG. 8A ray R₃₂, after refraction at the air/glass interface 234 as ray R₃₄ reflects off the face 232b such that the reflected ray R₃₅ passes near, but over vertex 233 and thus does not strike the bus wire 214 a second time. This ray R₃₅ arrives at the glass/air interface 234 at an internal interface angle α of 65° relative to a normal N_{g} to the interface and undergoes TIR as ray R₃₆ to be absorbed by the cell.

In FIG. 8B, incoming ray R₄₂ is incident on the glass interface 234 at a larger external interface angle γ=18° than ray R₃₂ (γ=7.5°) in FIG. 8A. After refraction at the air/glass interface 234, ray R₄₄ hits the bus wire 214 twice, once each on adjacent, oppositely facing faces 232b and 232a as ray R₄₃. However, this ray, does undergo TIR as ray R₄₆, because it arrives as R₄₅ at the glass/air interface 234 at an internal interface angle α of 48° relative to the normal N_{g} to the interface 234, which exceeds αₘᵢₙ, reflecting it to the absorber 218, where it is absorbed.

In FIG. 8C, incoming ray R₅₂ is incident on the interface 234 at an even larger external interface angle (γ=29°) than ray R₄₂. Once again, this ray, hits two faces 232b and 232a, as rays R₅₄ and R₅₃, respectively. However, in this case, the reflection R₅₅ from the second face 232a, hits the interface 234 at too small an internal interface angle α relative to the perpendicular N_{g} to the interface (α=41°<αₘᵢₙ) and does not undergo TIR at the glass/air interface 234, but rather, escapes as ray R₅₆. For the representative case of a bus wire with faces at β=+/−60 degrees and glass/encapsulant with an index of refraction of 1.5, the maximum external interface angle γₘₐₓ relative to the normal of the glass at which a ray can be incident, undergo a second reflection off the bus wire and still undergo TIR, is approximately 27.6°.

FIGS. 8D and 8E show rays R₆₂, R₇₂, which hit near the crest 233 of the faces. In FIG. 8D, ray R₆₄, which has an external interface angle γ of 34°, larger than any of the external interface angles γ shown in FIGS. 4A, 4B, 8A, 8B, 8C, after refraction at the air/glass interface 234, reflects off the face 232b such that the reflected ray R₆₅ passes near, but over crest 233. This reflected ray hits the glass/air interface 234 at a very large internal interface angle α relative to the normal to the interface N_{g} (far to the left of the portion of the device shown) and will achieve TIR. Comparing FIGS. 8A and 8D, it is seen that this condition of the reflected ray passing over but near the adjacent crest 233 occurs at very different external interface incident angles γ of the incoming ray, e.g., R₃₂, R₆₂. The difference in outcome whether TIR occurs or not is due only to where on the face the refracted ray strikes relative to the crest 233 and trough 237.

In FIG. 8E, ray R₇₂ is incident on the interface 234 at a larger external interface angle (γ=45°) than ray R₆₂ (γ=34°) in FIG. 8D. After refraction at the air/glass interface ray R₇₄ hits the bus wire 214 twice, once each on adjacent faces 232b and 232a as rays R₇₄ and R₇₃, respectively. It arrives at the glass/air interface at too small an internal interface angle α=32°<αₘᵢₙ relative to the normal N_{g} to the interface 234, and escapes. Note that in the case of incidence near the crest 233 of the face, there is no analog to FIG. 8B. That is, there is no condition where the ray strikes two adjacent faces 232b and 232a and still undergoes TIR.

Thus, it is not strictly possible to specify a range of external interface angles γ within which TIR will occur for all incoming light rays, because additional determining factors are whether the ray strikes a face having a normal on the same or opposite side of the normal to the external glass interface, and also where along the face between the crest and the trough the ray strikes. Thus, within a general range of external interface angles γ, defined by a maximum angle γₘₐₓ for which TIR does occur, there will be sub-ranges or bands having smaller external interface angles, where TIR does not occur for every ray, for the reasons just explained.

The patterned bus wire is far more tolerant of deviations from normal incidence for external interface angles in a plane P_{y} that is parallel to the v-grooves of the bus wire as shown in FIG. 6, than it is of deviations from normal incidence in a plane Pₓ that is perpendicular to the v-grooves, as shown in FIG. 5. For example as noted above for the representative case of +/−60 degrees and a media index of refraction of 1.5, a ray in the plane of FIG. 5 may be up to approximately +/−27.6 degrees and be guaranteed to undergo TIR. However, for rays in the plane of FIG. 6, a ray of any angle (up to +/−90 degrees) will be guaranteed to undergo TIR. Further, the range of angles that the projection of a ray onto the plane of FIG. 5 may assume and be captured by TIR is larger if there is also a component of the ray in the plane of FIG. 6. For example, for a ray which has equal components in the planes of FIGS. 5 and 6, the projection of the ray onto the plane of FIG. 5 may be up to approx. +/−35 degrees from the vertical and still be guaranteed to undergo TIR, s compared to 27.6 degrees for a ray that lies wholly in the plane of FIG. 5.

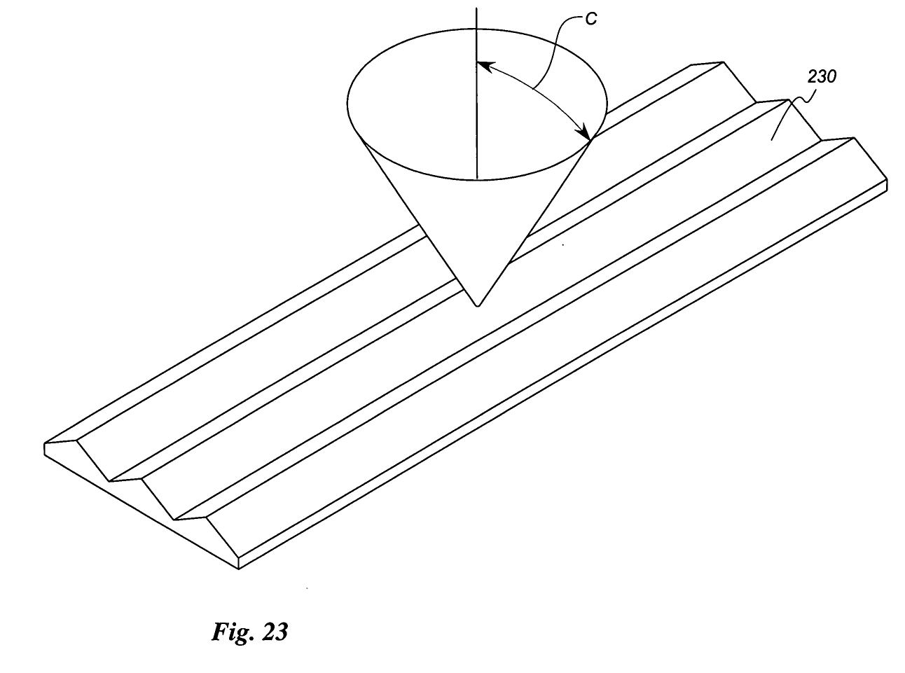

A concise way to summarize the ability of the system to capture light by TIR is to define a cone of angle C as shown in FIG. 23. For the representative case of a face angle of between +/−60 degree and media refraction index of 1.5, all the light that is incident within a cone of angle 27.6° will be captured by TIR. Numerical analysis shows that over 50% of the light, when illuminated omni-directionally, that is incident at a point will be captured (corresponding to a cone of 90°, i.e., a hemi-sphere).

### EXAMPLE

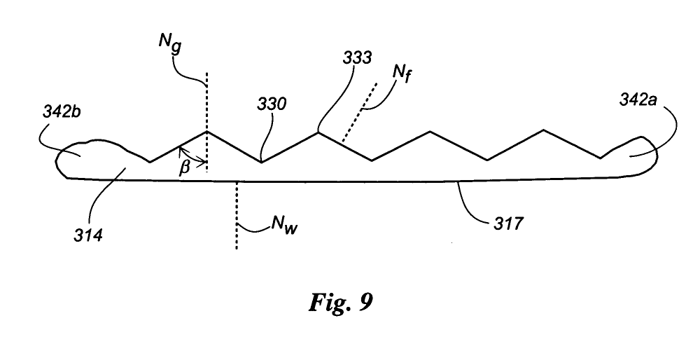

Grooves were rolled into tinned copper flat wire using a diamond turned mandrel rolling tool as described later. FIG. 9 shows schematically a cross section of the rolled wire 314. The distance between crests 333 is three hundred microns. The nominal angle β of the face 332a, 332b relative to a normal N_{g} to the glass/environment interface (and also typically, and as shown in this case, relative to a normal to the plane defined by the back surface 317 of the bus wire) is +/−62°. This angle was designed as a result of a one-dimensional ray-tracing simulation where a distribution of angles was assigned to the incoming solar energy and the total amount of light recaptured to the bus wire was maximized as a function of the face angle β. In the simulation, the distribution of external interface angles γ was all in a plane Pₓ that is perpendicular to the grooves, as shown in FIG. 5. As compared with the +/−60° angles of FIGS. 3, 4A, 4B and 8A-8E, the angle of +/−62° provides a bit more margin against the conditions of FIGS. 8C and 8E, where light is not trapped. The edges 342a, 342b of the sample bus wire are imperfectly formed and could be made to be more precise. It is also appropriate to include a second dimension to take into account components of incoming rays that lie in a plane P_{y} that is parallel to the grooves, as shown in FIG. 6, which may result in a different angle than 62°. As discussed above, also, for different indices of refraction, the range of face angles might be as large as from +/−50° to +−/70°.

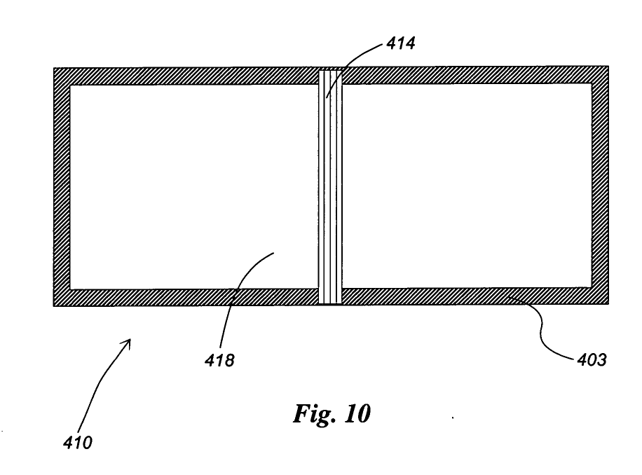

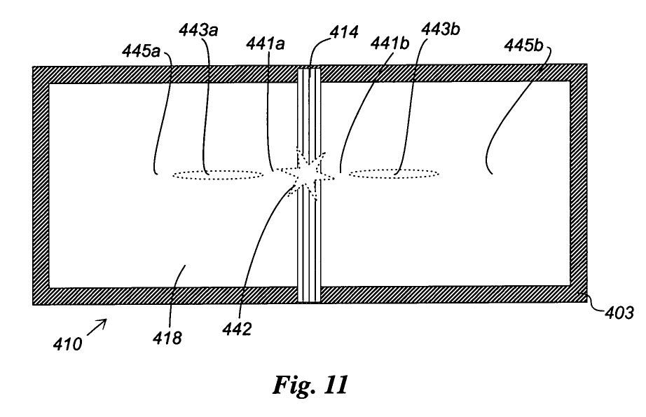

A patterned bus bar 414 (as shown as 314 in FIG. 9) was then applied to a test cell 410, illustrated in FIG. 10. The cell was fabricated of cast multi-crystalline silicon, with phosphorous diffusion, silicon nitride anti-reflection coating, aluminum back surface field and a front metallization of silver paste. The metallization consists of a 75 mm wide frame 403 with no gridlines, to be able to accurately measure the amount of light captured back onto the cell surface 418 after TIR. The low currents involved allow for this practice. The patterned bus wire 414 was then silver epoxied to a center busbar (not shown) of the metallization 403. This cell was laminated using EVA and a superstrate of 3 mm thick low-iron float glass.

FIG. 11 shows schematically the view taken from above, but not directly above this cell 410, under laser illumination normally incident on the patterned bus wire 414. The laser strikes the bus bar 414 and makes a relatively bright spot 442, which impinges across most of the width of the bus wire 414. Light also illuminates the cell surface 418 along lines 443a, 443b. These are the result of reflections from the interface between the glass surface and the external environment. They are visible because the absorbing properties of the cell surface 418 are imperfect, and light scatters in all directions when it strikes the surface after TIR.

Thus, there is significant recapture of light back onto the cell 418 after TIR.

It is believed that the illuminated lines 443a and 443b are not sharply defined regions, because of imperfections in the flatness of the face surfaces, which result in parallel rays of light being reflected from them over a range of angles rather than at just one angle. Thus, efforts taken to achieve flatter surfaces would be beneficial. It is also believed that imperfections in the sharpness of the crests and troughs contribute to the fuzziness of the illuminated regions, suggesting that in addition, light is reflecting from the crests and troughs at angles that result in escaping light. Thus, efforts to achieve sharp crests and trough creases would also likely be beneficial.

The three mW (nominal) laser impinged normally on the active portion of the cell with a resultant I_{sc} of 1.59±03 mA (six sites measured). With the light impinging on the bus wire as in FIG. 11, the I_{sc} (now due primarily to TIR) was 1.01±0.03 mA. Thus the photocurrent resulting from the laser striking the bus wire was 63.6% of that resulting from striking directly on active cell area. This ratio will be referred to herein as the Recapture Ratio. The surface of standard bus wire material is not perfectly specular. Therefore, some reflections from the bus wire may strike the cover to environment interface at an internal interface angle that is large enough so that TIR may take place. Some light (about 4%), reflected slightly away from perpendicular will also undergo normal reflection at the cover environment interface back to the absorber. A control experiment was performed on a test structure using conventional, untreated flat surface bus wire material. In this case, the Recapture Ratio was 5.8%, significantly less than the 63.6% of a patterned bus wire of an invention hereof. Depending on the degree of specularity of the surface, the Recapture Ratio for a standard flat bus wire might be higher, for instance 20%.

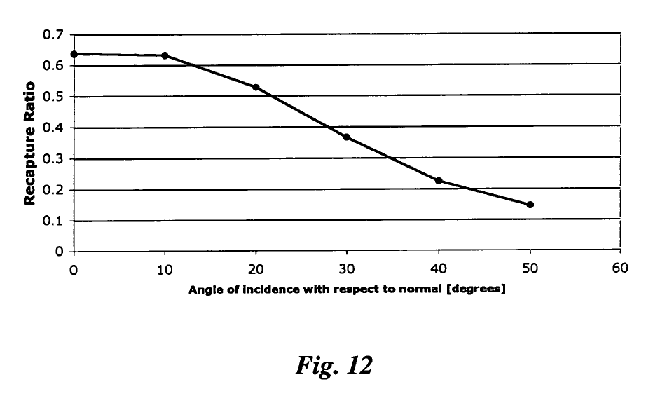

FIG. 12 shows the Recapture Ratio measured for a range of external interface angles of incident light, which light ray trajectories vary within the plane Pₓ, shown in FIG. 5. As expected, light is trapped over a wide range of external interface incident angles γ.

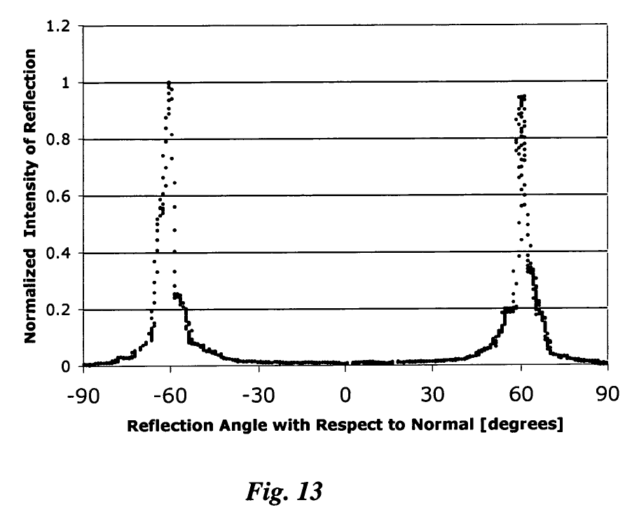

FIG. 13 shows a plot of the intensity of reflection from a patterned un-encapsulated bus wire, as a function of angle of reflection (measured from the normal) for the case of light which is incident normal to the plane defined by the back surface of the bus wire, which is also normal to the plane of the interface of the cover and the environment. These data were taken by shining a 650 nm red laser onto the patterned bus wire at normal incidence and rotating a photosensor in an arc centered at the bus wire. The photosensor output is an average over approximately 3° of rotation.

There are peaks at approximately +/−60°. These peaks represent the light that is incident on the straight portions of the sidewalls of the grooves in the bus wire. Fully 96% of the light is reflected at angles greater than the 42° minimum external interface angle αₘᵢₙ, relative to a normal to the glass, which will achieve TIR. Due to the size of the test cell, light that came off at an angle greater than 78° came back down outside the outer periphery of the cell and did not contribute to photocurrent. The portion of the response of FIG. 13 lying between −78° and −42° and between +42° and +78° was convolved with the dependence of cell output on angle of incidence and then multiplied by the published reflectivity for tin (0.8) to yield a prediction of the Recapture Ratio. The predicted Recapture Ratio of 70.3% is in the general range of the measured result.

The reason that the reflection angle graph is not two sharp peaks at 60° is that the face surfaces are not perfectly flat, and the peaks and valleys are not perfectly sharp.

Bus wire is typically made of soft copper with a coating of soft solder on it. These materials form extremely well by rolling. However, it is advisable that any layer of solder on the top of the a patterned bus wire of an invention hereof be thin, so that when it re-melts during soldering and moves under the influence of capillarity, the shape of the underlying layer is not altered to an unacceptable degree. Experimentally, it has been found that a thick solder layer may be wiped while molten to produce a suitably thin layer. Other techniques are known in the art. A thin layer of solder may actually be advantageous, as its re-flowing may smooth out microscopic texture unintentionally introduced by the rolling process.

It may be advantageous to use another metal on top of the bus wire, because solder has a reflectivity of only about 0.8. For example, the copper bus wire may be plated with silver. Alternatively, the bus wire may be made by laminating two or more different metals, for example silver and copper.

Typically, it is advantageous for the surface finish of the faces of the bus wire to be such that results in an optically specular surface.

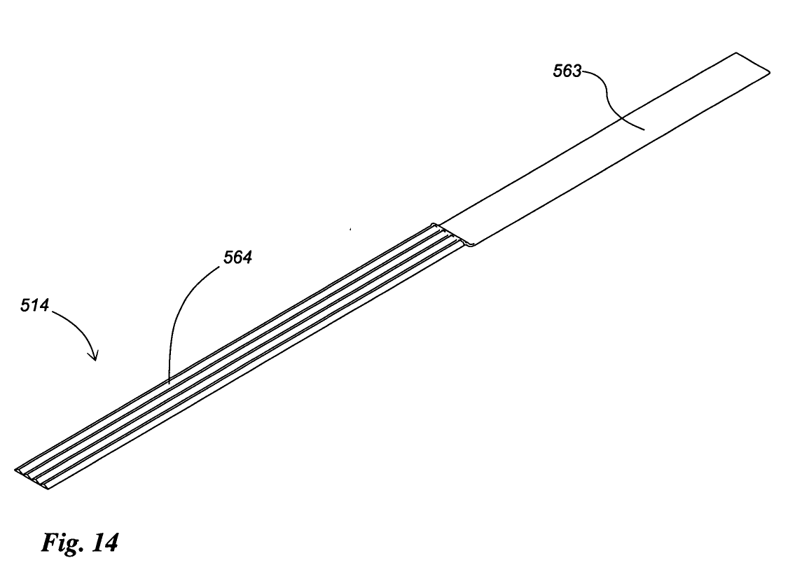

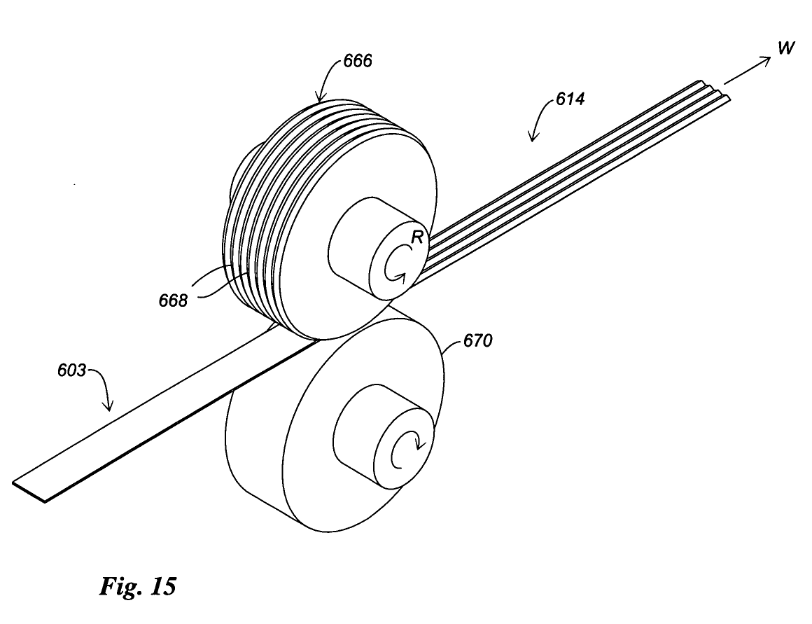

It may be advantageous to pattern only that portion of the bus wire that is soldered to the top of the cell and leave the portion that connects to the bottom of the adjacent cell un-patterned, so that the grooves do not interfere with soldering to the adjacent cell. FIG. 14 shows a bus wire 514 with a patterned portion 564 that will go on top of the metallization 112 of one cell and an un-patterned section 563 that will go underneath the adjacent cell (typically to a back surface metallization). Continuous rolls of bus wire material with alternating sections of patterned 564 and un-patterned 563 lengths can be provided to a module manufacturer by vendors. These continuous rolls can be cut and bent on the tabber-stringer (the machine which applies the bus wire material to the cell.) Alternatively, the patterning can be done at the tabber-stringer.

The bus wire material 614 may be patterned, using a rolling or other forming tool, for example, as shown in FIG. 15. For example, a rolling mandrel 666 may be fabricated with v-grooves 668 around its periphery as shown. Such a rolling mandrel may be made by diamond turning techniques known in the art. A stainless steel mandrel can be turned to the rough shape desired, but without the fine features needed to form the v-grooves. Nickel can then be electroformed onto the steel mandrel in the area of the v-grooves. The nickel can then be diamond machined to form the v-groove features. Diamond machining can be used so that the mandrel, as machined, has an optical surface finish. Alternatively, a mandrel may be machined with conventional tools, and then polished. However, during the polishing, some amount of rounding of corners may take place, resulting in a form that is less ideally suited to the task at hand. In FIG. 15, the rolling mandrel 666 rotates in the direction of arrow R and is opposed by an idler roller 670, which backs up the material 603, which moves in the direction of the arrow W, so that forming pressure is created.

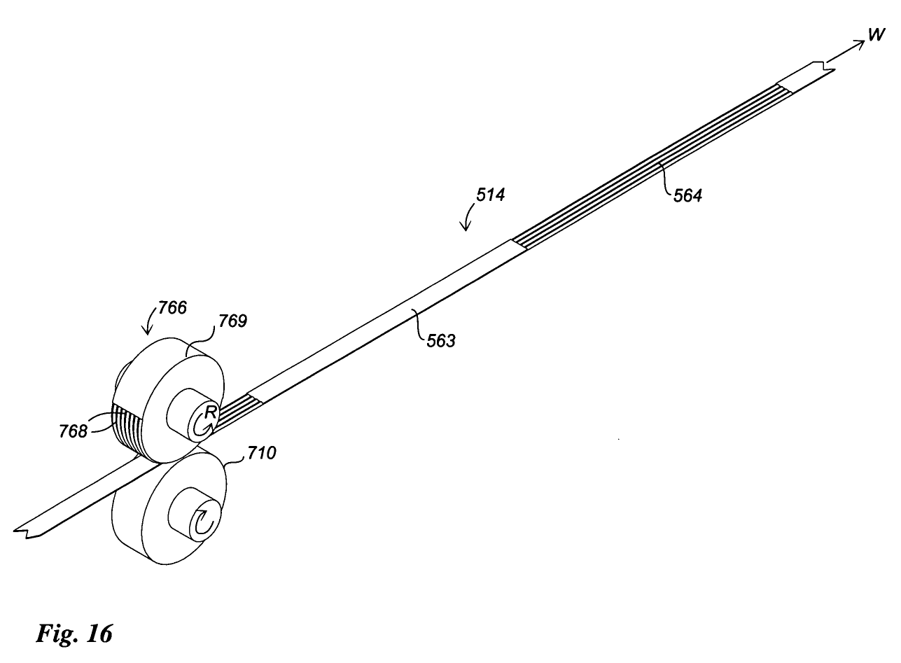

FIG. 16 shows the forming of an interrupted bus wire 514 of FIG. 14 where the rolling mandrel has both a forming section 768 and a flat section 769, to form grooved regions 564 and flat regions 563 of the bus wire 514.

While the fundamental concept provides for light trapping over a reasonable range of incident external interface angles γ (see FIGS. 4A and 8A, 8B and 8D), additional variation can optimize the design of the grooves, with an objective of maximizing total light capture. Such variation would depend upon module mounting orientation and angle, as well as daily and seasonal variation of solar incidence.

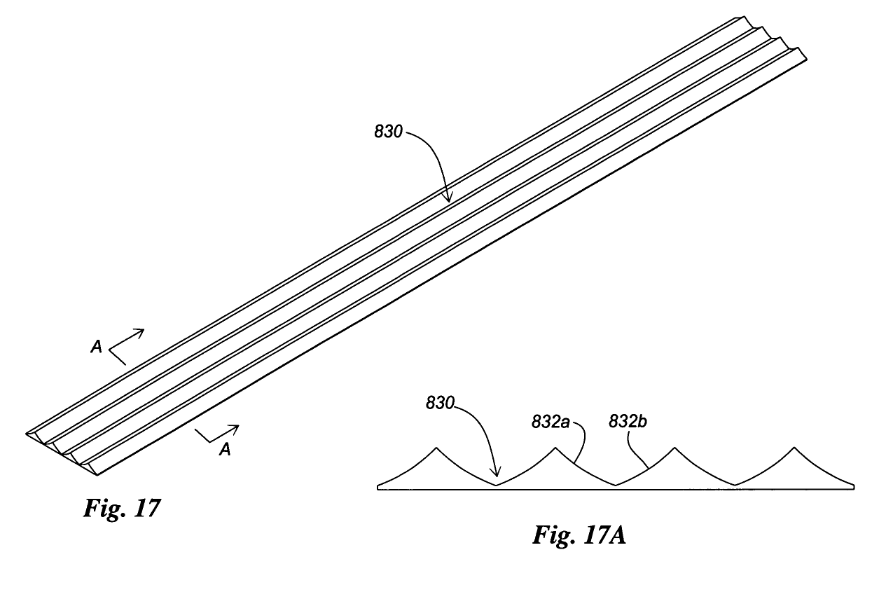

As shown in FIGS. 17 and 17A, which is a cross-section of FIG. 17 along the lines A-A, the faces 832a, 832b of grooves (shown as v-grooves in this case) 830, need not be planar. FIG. 17 shows a profile of the faces 832a, 832b that will result in fewer rays suffering two collisions than a planar face case. The faces shown in FIG. 17 are congruent, meaning they are superposible so as to be coincident throughout. Some are also mirror images of congruent shapes.

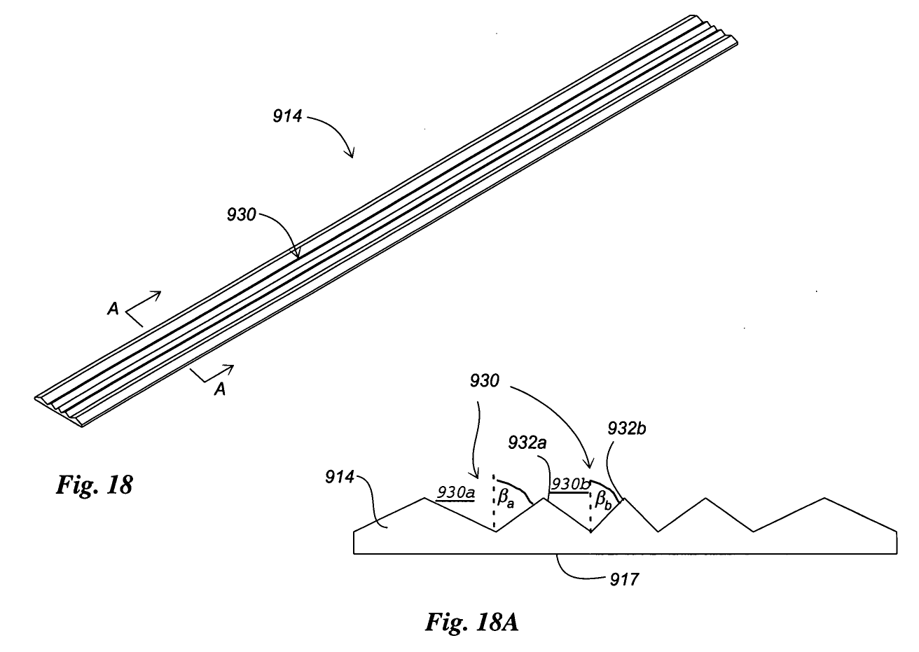

As shown in FIG. 18, and FIG. 18A, which is a cross-section of FIG. 18 along the lines A-A, the profile need not have the same face angle β for all V-grooves 930. Some of the grooves 930a may have relatively larger included face angles βₐ, as compared to other grooves 930b with smaller included face angles β_{b}. Further, the faces 932a, 932b need not be symmetrically angled relative to a line that is perpendicular to the back surface 917 of the bus wire strip 914.

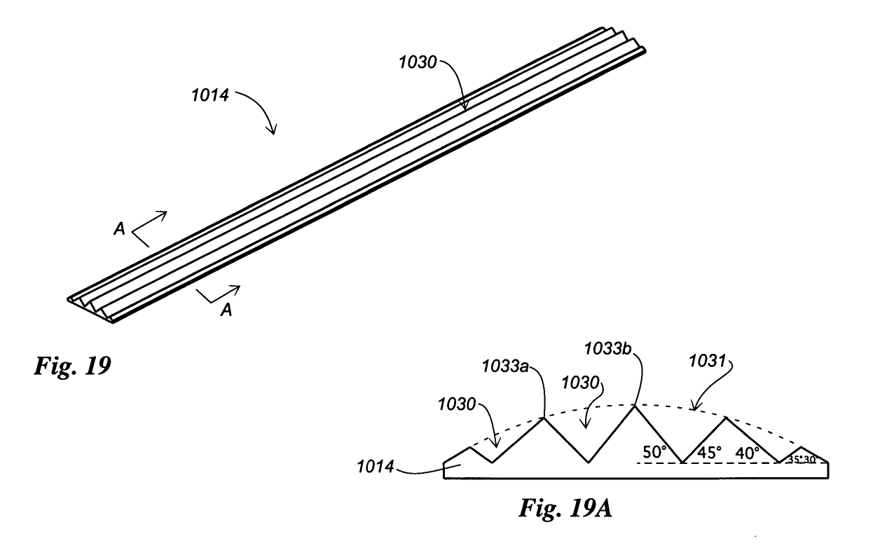

As shown schematically in FIGS. 19 and 19A, which is a cross-sectional view of FIG. 19 along the lines A-A, the profile need not be imposed on a flat surface. Here, adjacent crests 1033a, 1033b of adjacent grooves 1030 lie along the surface of a shape 1031, indicated by a dashed line, such as a circular arc, or other appropriately chosen curve. Adjacent face angles also differ, as indicated.

Any combination of the foregoing variations may be used, such as non-planar, congruent faces, at different angles, along a surface that is not flat, with different face sizes.

The profile can be of a wide range of size scales. Typically, the size of faces (length from crest to trough) will be on the order of, or larger than, the wavelength of light that is to be reflected, to avoid diffraction effects. For example, in a photovoltaic application with crystalline silicon solar cells, the faces will be at least one micron in size. In many embodiments, the size of the faces will be about 5 microns to about 150 microns, and more frequently from about 25 microns to about 100 microns. The faces need not all be the same size. Further non-planar faces can be of different sizes from each other, while being the same shape. The spacing between crests for an example with a 60° face angle will be between about 10 microns to about 300 microns, and more typically between about 50 microns and about 200 microns.

An advantage of relatively larger features is that, typically, although an idealized V-groove is desired, the groove as fabricated will have somewhat rounded crests 333 (FIG. 9) and troughs 330. Some of the light that reflects from the rounded portion of the surface will be reflected toward the glass superstrate at too small an internal interface angle away from the perpendicular to the interface for TIR and hence, will not be captured back onto the absorber cell. Larger features mean that this rounding comprises a smaller percentage of the total bus wire surface, hence reducing the percentage loss due to rounding.

However, another factor may limit the size of the features that are formed. The material that has been formed, for example by rolling, undergoes work hardening and is no longer completely soft. This may cause a problem in that it limits how tight a bend can be created and makes the material more susceptible to failure due to repeated flexing that takes place in the module as temperature and loading conditions of the module change. Larger features mean that a larger fraction of the bus wire material has been work hardened. One solution is to anneal the material after forming. A complimentary solution is to limit the size (and therefore depth) of the features to reduce the fraction of material that is work hardened.

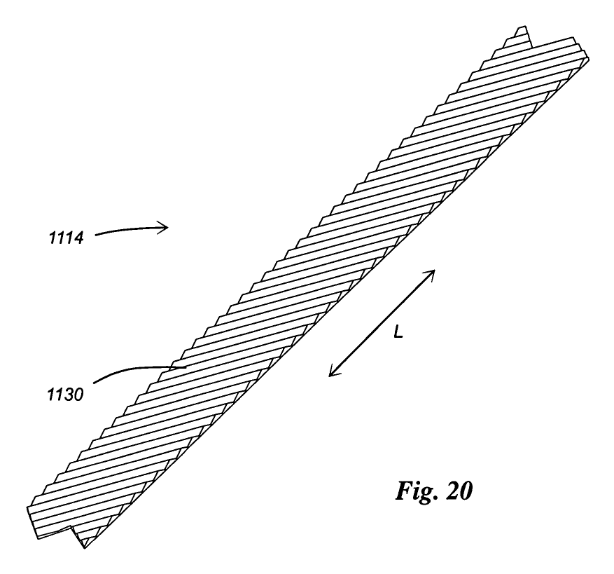

Variations and extensions of the foregoing discussion are illustrated with further reference to FIG. 20. The grooves 1130 need not run parallel with the long dimension L of the material of the bus wire 1114 but may be inclined at any angle with respect to the long dimension. FIG. 20 shows such grooves 1130 inclined at an angle of 45° to the long dimension L.

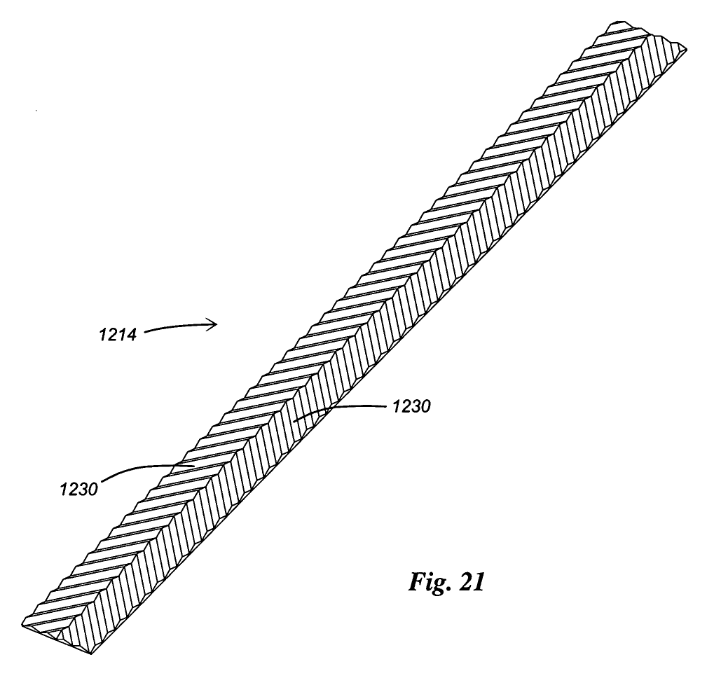

The grooves need not be straight. FIG. 21 shows chevron shaped (along the long dimension) grooves 1230 extending across and along the bus wire 1214.

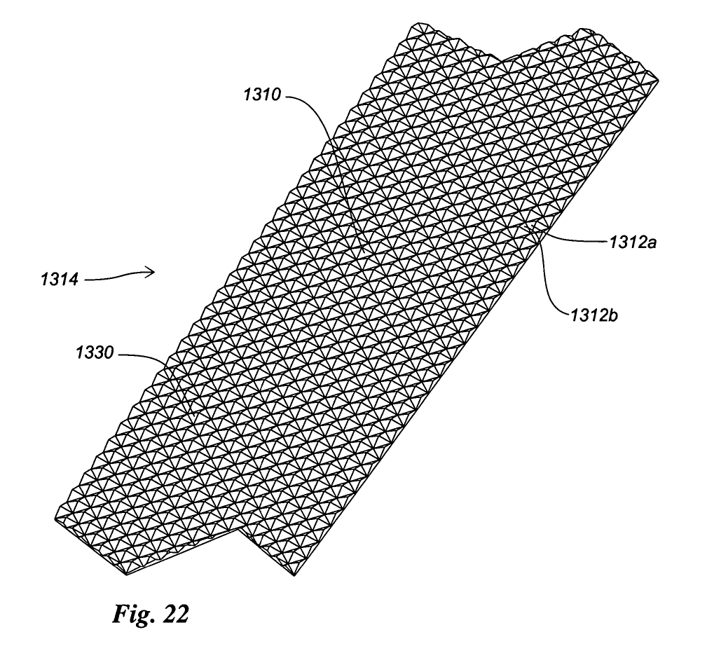

Patterns other than v-grooves may also be used, so long as they reflect incident light off at large internal interface angles α, which will be reflected from the superstrate and atmosphere interface to the protrusion surface. For example, as shown in FIG. 22, a pattern of faces that constitute pyramidal protrusions 1310 may be used for a bus wire 1314. Such a pattern may have advantages in visual effect. However, a disadvantage of such patterns is that a higher percentage of light penetrates down near the base of the depressions 1330 before hitting a surface and reflecting, as compared with a v-groove pattern of FIG. 3. If the light is not normally incident, more of the light will suffer two reflections (from the base of adjacent pyramids 1312a, 1312b) as compared to the V-groove 230 and more of the light will escape the module without TIR.

It is advantageous for the solar module to be able to capture light that is incident over a wide range of external interface angles γ. In this way, light can be collected even when the sunlight is diffuse (on a cloudy day). In addition, the angle of the sun changes over the course of the day and over the course of the seasons. A stationary panel (one that does not track the sun) should be able to collect the sun's rays over a range of angles.

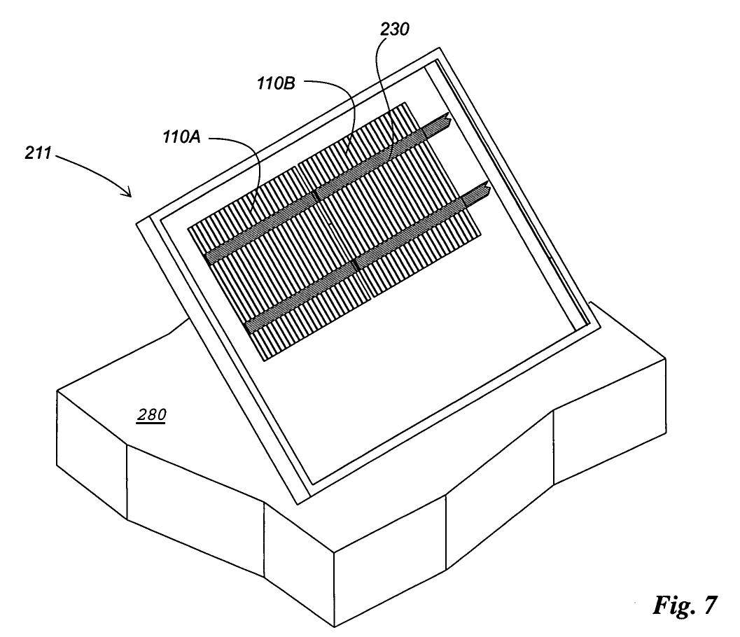

FIG. 7 shows a module 211, composed of two cells 110A and 110B, as shown in FIG. 2, mounted at a fixed angle of ζ degrees with respect to the ground. (For simplicity, only two cells 110A, 110b are shown but typically, many more would be present). Typically, it is desirable that this angle ζ be larger, the higher the latitude of the geographic location where the module is mounted and lower at lower latitudes.

FIG. 7 shows a particularly advantageous orientation of the patterned bus wires 214 of the current invention with the grooves 230 of the bus wire mounted horizontally. This is advantageous because over the course of each day, the angle of incidence of the rays of sunlight on the module vary over a very wide range—going from a grazing angle in one direction in the early morning to a grazing angle in a widely different direction in the late afternoon. In contrast, the angular change over the course of the seasons is relatively much smaller (at most latitudes). For the orientation of FIG. 7 where the grooves of the patterned bus wire are horizontal, the smaller angular change associated with seasons can be thought of as changes in incident rays which lie in plane Px in FIG. 5. This angular change can be accommodated as shown in FIGS. 3, 4A, 4B, and 8A-E. A major component of the angular change that takes place daily lies in the plane Py. As noted, the current invention is very tolerant of changes of angles in this plane. As a consequence, the bus wire orientation shown in FIG. 7 will tolerate the large angular changes that take place daily as well as the smaller angular changes that take place seasonally.

Some solar cell modules have a superstrate 222 (FIG. 3) that is a simple, single sheet of material. Others may have such a sheet that is coated with one or more coatings, such as an anti-reflective, or other coating. The designer does need to consider the transmission and reflection properties of the various layer interfaces that the coatings give rise to. However, in general, the inventions disclosed herein will work in the same manner. Light must reflect from the interface between the environment and the outermost coating layer, or, perhaps, from an intermediate layer back to the cell surface to be recaptured. Thus, as used herein, the environment-superstrate interface may mean the interface between the environment and a single sheet of material, or a coated sheet of material. In other words, for purposes of naming the interface, the coatings are considered to be part of the superstrate itself.

Some superstrates have a surface texture, intended to aid in light capture or to change the visual appearance of the module. The nature of the texture may alter the optimum design of the bus wires as the texture affects both the refraction of the incoming rays and the TIR of the rays reflected from the bus wire.

Another aspect of an invention hereof is an aesthetic variation in the appearance of solar panels, which is advantageous for some circumstances. A common concern is that while the solar cell absorbers themselves appear to be dark, in part because most of the light that strikes them is absorbed, the conventional bus wires appear bright and shiny because much of the light which strikes them reflects back out of the panel (and can hence be seen by an observer). From close and moderate viewing distances, the bright bus wires are a major visual element. As architectural integration is an important application for photovoltaic elements, this visual appearance is considered an impediment to use in some circumstances. Light trapping bus wires of an invention hereof appear dark when encapsulated as part of a solar panel. This is because the light that enters the module and hits the bus wire is mostly trapped internal to the panel by TIR and does not escape. Thus there is far less light available to reach an observer and the bus wires appear dark. Typically, the bus wires appear to be a medium to dark shade of grey. This grey presents much less of a visual contrast to the dark blue or black of typical solar cell absorbers.

The designer will understand that the overall Recapture Ratio any bus wire surface pattern produces is a combination of its instantaneous Recapture Ratio at different times of a day, over the course of a year. The instantaneous Recapture Ratios will in turn depend on a multiplicity of factors including: the angle of incidence of light from the sun, the degree of direct versus diffuse sunlight, the geographic location, the angle and orientation of mounting of the module, whether or not the module is fixed mounted or tracks the sun, the surface texture on the top of the glass, and the specific design of the bus wire. Thus, specifics of the intended application (geography, climate, nature of mounting, desired season of highest yield, etc) can be used to design bus wires that provide superior performance, when appropriate.

The foregoing discussion typically assumes the metallization includes gridlines and a bus bar. However, a bus bar need not be present. A bus wire of an invention hereof with inclined faces may be applied directly to a light absorber surface, overlying the gridlines. If a bus bar is present, the textured bus wire may cover the bus bar completely, or may cover only part of the bus bar. It may also extend beyond the area of the bus bar.

There may be other components of a solar light absorbing cell, or system, that are, for some reason, not considered to be conventional bus wires, but for which an invention disclosed herein is applicable. In general, the invention can be applied to any reflective portion of a solar cell module where the metallic portion exists as a free standing metallic strip or sheet before it is contacted, applied, or adhered, or otherwise secured to the semi-conductor light absorbing elements. The reflective element must be able to be patterned before and independently from the step by which it is contacted, applied, or adhered, or otherwise secured to the solar cell elements. For instance, to the extent that in the future, other elements, such as gridlines, or fingers are applied as free-standing strips which can be patterned, then they too can be patterned according to the principles discussed herein, and light will reflect from them, onto light absorbing portions of the cell.

The foregoing has described using a rolling method to apply the inclined faces to the bus wire reflective surface. Other methods may also be used, including but not limited to: drawing, extrusion, stamping and embossing.

### Partial Summary

One preferred embodiment of an invention hereof is a method of making a photovoltaic device, comprising the steps of: providing a light absorber contacted by a metallization; and providing at least one preformed elongated, bus wire, comprising: a light reflecting surface and an obverse base surface; and the reflecting surface comprising a plurality of faces inclined relative to each other. Further steps comprise placing the bus wire on the absorber, contacting the metallization; and placing an encapsulant and a light transparent cover over the bus wire and the absorber, the cover having an external surface, so that at least two of the faces are inclined at face angles relative to the external surface of the cover. The faces, the cover and the absorber are arranged and the indices of refraction of the cover and the encapsulant are chosen so that light that strikes the bus wire along a line that is perpendicular to the cover external surface, reflects from the bus wire to an interface of the cover and an outside environment and undergoes Total Internal Reflection (TIR) to the absorber.

The faces of the bus wire may comprise specular surfaces.

The faces, and the absorber may be arranged so that at least 20% of the light that strikes the bus wire along the line that is perpendicular to the cover external surface undergoes TIR to the absorber.

The faces and the absorber may be arranged so that at least 50% of the light that strikes the bus wire as omnidirectional illumination undergoes TIR to the absorber.

The faces may comprise planar or/and non-planar surfaces. The faces may comprise a plurality of pairs of adjacent faces, each pair meeting at a crest. The faces may comprise two sets of congruent surfaces inclined at face angles relative to a line that is perpendicular to the cover external surface. The face angles may be of equal or different magnitudes.

One set of surfaces may comprise faces with positive face angles, the other of the two sets may comprise faces with negative face angles, with a positive angle face meeting a negative angle face at a crest.

Adjacent crests between the plurality of faces may be separated at a spacing of between approximately 10 microns and 300 microns and preferably between approximately 50 microns and 200 microns.

The inclined faces, the cover and the absorber may be arranged such that light that strikes the bus wire along a line perpendicular to the cover external surface reflects and strikes the external surface of the cover at an internal interface angle of greater than about 42° relative to a line perpendicular to the cover external surface.

The faces may be arranged in a pattern comprising grooves that extend substantially parallel or inclined relative to the dimension of elongation of the bus wire.

The faces may be arranged in a pattern comprising a plurality of V-shaped grooves or a plurality of pyramids. The faces may be arranged in a pattern comprising a plurality of pairs of V-shaped grooves, at least one pair forming a chevron.

The face angles may be between 50° and 70° and preferably between 55° and 65°.

The bus wire may comprise a rolled surface, or a surface that has been stamped, embossed, extruded or drawn. The bus wire light reflecting surface may comprise a surface to which faces have been applied before contacting the bus wire to the absorber.

The step of contacting the bus wire to the metallization may comprise soldering.

The metallization may comprise a bus bar, the step of placing the bus wire may comprise placing it so that it contacts and at least partially overlies the bus bar. The metallization may comprise a network of gridlines, the step of placing the bus wire may comprise placing it so that it contacts and overlies at least one gridline. The reflecting surface may comprise silver, which may be a plating.

The photovoltaic device may comprise a solar cell.

A similar invention hereof is a method where the step of placing the bus wire on the absorber is conducted after a step of forming the faces on the bus wire reflecting surface.

A related method invention hereof further comprises the steps of: providing a second photovoltaic device as produced by a method described above; and electrically coupling the second photovoltaic device to the first photovoltaic device by establishing electrical continuity from the bus wire of the first photovoltaic device to the second photovoltaic device, thereby forming a string of photovoltaic devices.

Still another related method further comprises providing a third photovoltaic device as produced by a method described above; and electrically coupling the third photovoltaic device to the first string of photovoltaic devices by establishing electrical continuity from a bus wire of the first string of photovoltaic devices to the third photovoltaic device.

Yet another invention hereof is a method of making a photovoltaic device, comprising the steps of: providing a light absorber contacted by a metallization; providing at least one preformed elongated, bus wire, comprising: a light reflecting surface and an obverse base surface; the reflecting surface comprising a plurality of faces inclined relative to each other; placing the bus wire on the light absorbing device contacting the metallization; and placing an encapsulant and a light transparent cover over the bus wire and the absorber, the cover having an external surface, so that the faces are inclined, each at a face angle relative to the external surface of the cover. The faces, the cover and the absorber are arranged and the indices of refraction of the cover and the encapsulant are chosen so that substantially all of the light that strikes the cover external surface at any external interface angle less than 27 degrees relative to the perpendicular to the cover surface, reflects from the bus wire to an interface of the cover and an outside environment and undergoes TIR to the absorber.

A still additional useful embodiment of an invention hereof is a method of making a photovoltaic device, comprising the steps of: providing a light absorber contacted by a metallization; providing at least one preformed, elongated bus wire, comprising: a light reflecting surface and an obverse base surface; the reflecting surface comprising a plurality of faces inclined relative to each other; placing the bus wire on the light absorbing device contacting the metallization; and placing an encapsulant and a light transparent cover over the bus wire and the absorber, the cover having an external surface, so that the faces are inclined, each at a face angle relative to the external surface of the cover. The faces, the cover and the absorber are arranged and the indices of refraction of the cover and the encapsulant are chosen so that 50% of the light that strikes the bus wire as omnidirectional illumination reflects from the bus wire to an interface of the cover and an outside environment and undergoes TIR to the absorber.

Any of the more specific details regarding face angles, crest arrangements, methods of applying the faces to the wire, etc., mentioned above, may be a feature of these last two mentioned related embodiments.

Yet another preferred embodiment of an invention hereof is a photovoltaic device comprising: a light absorber having a metallization contacted thereto; and contacting the metallization, at least one preformed elongated bus wire, comprising: a light reflecting surface and an obverse, base surface; the reflecting surface comprising a plurality of inclined faces. Overlying the at least one bus wire and the absorber is an encapsulant and a light transparent cover, the cover having an external surface relative to which at least two faces are inclined at face angles. The inclined faces, the cover and the absorber all are arranged so that light that strikes the conductor along a line that is perpendicular to the cover external surface, reflects from the bus wire to an interface of the cover and an outside environment, undergoing TIR to the absorber.

With a related embodiment, the faces, and the absorber are arranged so that at least 20% of the light that strikes the bus wire along the line that is perpendicular to the cover external surface undergoes TIR to the absorber.

Related embodiments of photovoltaic devices of inventions here of include photovoltaic devices having all of the specific variations and descriptions of geometry, surface arrangement, etc., mentioned above in this summary section with respect to the methods of making a photovoltaic device described.

An additional related embodiment of an invention hereof comprises a second photovoltaic device as described above, electrically coupled to the first photovoltaic device, the second photovoltaic device being coupled to the first photovoltaic device by electrical continuity from the bus wire of the first photovoltaic device to the second photovoltaic device, thereby forming a string of photovoltaic devices.

There may further be, a third photovoltaic device as described above, electrically coupled to the string of photovoltaic devices described, the third photovoltaic device being electrically coupled to the first string of photovoltaic devices by electrical continuity from a bus wire of the first string of photovoltaic device to the third photovoltaic device.

For a related embodiment of a device hereof, the electrical continuity from the bus wire of the first photovoltaic device to the second photovoltaic device may comprise an end portion of the bus wire of at least one of the first and second photovoltaic devices. An end portion of the bus wire of at least one of the first and second photovoltaic devices may bear inclined faces. Alternatively, an end portion of the bus wire of at least one of the first and second photovoltaic devices may be free of inclined faces.

Another important preferred embodiment is a method of forming a buswire comprising the steps of: providing a wire having a first surface and an obverse, base surface that defines a base plane; and forming on the first surface, a plurality of specular light reflecting faces that are inclined at face angles having magnitudes between 50° and 70° relative to a line that is perpendicular to the base plane.

Regarding the method of forming a buswire, adjacent faces of the plurality of faces may meet at crests that are separated at a spacing of between approximately five microns and three hundred microns and preferably at a spacing of between approximately fifty microns and two hundred microns. The size of a face, may also be within the same ranges, both general and preferred.

With this embodiment of a method of forming a buswire, the faces may be arranged in a pattern comprising substantially parallel grooves that extend along the dimension of elongation of the conductor. Or, parallel grooves may be inclined relative to the dimension of elongation of the conductor. The faces may be arranged in a pattern comprising a plurality of V-shaped grooves, or pairs of V-shaped grooves, at least one pair of which may form a chevron pattern. The faces may also be arranged in a pattern comprising a plurality of pyramids.

Related methods of an invention hereof of forming a bus wire comprise steps of forming a buswire where the faces comprise planar or non-planar surfaces. The surfaces may be arranged such that pairs of adjacent faces meet at a crest.

According to still another embodiment of a method of forming a buswire, the step of forming faces may comprise forming faces comprising two sets of congruent faces inclined relative to a line that is perpendicular to the base plane. The face angles may be of equal or different magnitudes.

In a beneficial embodiment of a method of an invention hereof, the step of forming faces may comprise rolling a tool along the wire. Alternatively, or in addition, the step of forming faces may comprise stamping faces upon the first surface of the wire.

Yet another related embodiment of a method of an invention hereof further comprises the step of applying silver to the wire on the first surface, which step of applying may be by plating.

With some embodiments of methods hereof, the step of forming faces may comprise forming alternating lengths of wire carrying the faces, and without the faces.

Another important preferred embodiment of an invention hereof is a bus wire comprising: a free-standing elongated electrical conductor having a light reflecting surface and an obverse, base surface which defines a base plane, the reflecting surface comprising a plurality of specular faces that are inclined, at face angles having magnitudes between 50° and 70° relative to a line that is perpendicular to the base plane.

As with the method embodiment just discussed, and others, adjacent faces of the plurality of faces may meet at crests that are separated at a spacing of between approximately five microns and three hundred microns and preferably between approximately fifty microns and two hundred microns.

The faces may be configured and arranged in all of the manners just discussed in connection with the method of forming a bus wire having specular light reflecting faces that are inclined at face angles having magnitudes between 50° and 70°, including in a pattern comprising substantially parallel grooves that extend along the dimension of elongation of the conductor or inclined relative thereto. The faces may comprise planar and non-planar surfaces. The face angles may be of equal or different magnitudes. They may be arranged in a pattern comprising a plurality of V-shaped grooves, a plurality of pyramids, a plurality of pairs of V-shaped grooves, at least one pair forming a chevron. The bus wire may comprise a rolled surface, or a stamped, embossed, extruded or drawn surface. The surface may be one to which the faces have been added, or that was formed with the faces in situ as the surface is formed, such as by extrusion or drawing. The reflecting surface may comprise silver, which may be a plating. The reflecting surface may comprise alternating lengths carrying the faces, and without the faces.

Yet another embodiment of a method of an invention hereof is a method of making a buswire for use with a photovoltaic device, the photovoltaic device having a light absorber contacted by a metallization, the method of making a buswire comprising the steps of: providing at least one elongated wire, comprising a first surface and an obverse base surface; and forming on the first surface, a plurality of specular light reflecting faces inclined relative to each other. The faces are arranged so that, when the formed bus wire is placed on the absorber with the obverse surface contacting the metallization, and when an encapsulant, and a light transparent cover having an external surface, are placed over the bus wire and the absorber so that at least two faces are inclined at face angles relative to the cover external surface, light that strikes the bus wire along a line that is perpendicular to the cover external surface, reflects from the bus wire to the interface of the cover and an outside environment, and undergoes TIR to the absorber.

In a related embodiment thereto the faces are arranged so that at least 20% of the light that strikes the bus wire along the line that is perpendicular to the cover external surface undergoes TIR to the absorber. With yet another related method, the faces, are arranged so that at least 50% of the light that strikes the bus wire as omnidirectional illumination undergoes TIR to the absorber.

As with most, if not all of the embodiments of methods and apparatus discussed above in this Summary section, there are many related more specific descriptions of the method of making a bus wire for use with a photovoltaic device.

The faces may comprise planar and/or non-planar surfaces. Adjacent faces may meet at a crest, which may be separated at a spacing of between five microns and three hundred microns and preferably fifty microns and two hundred microns. The face angles may be of equal or different magnitudes between 50° and 70° and preferably between 55° and 65°. The inclined faces, may be arranged such that light that strikes the bus wire along a line perpendicular to the cover external surface reflects and strikes the external surface of the cover at an internal interface angle of greater than about 42° relative to a line perpendicular to the cover external surface.

The faces may be arranged in a pattern comprising grooves that extend substantially parallel the dimension of elongation of the bus wire, or inclined relative to the dimension of elongation of the bus wire. The faces may be arranged in a pattern comprising a plurality of V-shaped grooves or pairs of V-shaped grooves, forming at least one chevron.

The step of forming faces may comprise rolling a tool along the wire, either with a tool having a continuous face forming section along a wire or a face forming section and a flat section. Instead of rolling, the faces may be formed by steps of stamping, embossing, extruding or drawing, or a combination thereof.

Additional related embodiments relate to a bus wire for use with a photovoltaic device having a light absorber, an encapsulant and a light transparent cover having an external surface, the bus wire comprising: a free-standing elongated electrical conductor having a light reflecting surface and an obverse, base surface. The reflecting surface comprises a plurality of specular faces that are inclined, relative to each other, such that when the base surface contacts an absorber, and an encapsulant and a cover overlie the conductor and the absorber, light that strikes the conductor along a line perpendicular to an external surface of the cover reflects from the conductor to an interface of the cover and an outside environment and undergoes TIR to the absorber.

As with the other major embodiments mentioned above in this Summary section, similar additional specific embodiments of components and steps are present with this related embodiment.

Yet another invention disclosed herein is a method of installing a photovoltaic device at a geographical location. The method comprises the steps of providing a photovoltaic device comprising: a light absorber, and a metallization contacted thereto; contacting the absorber at the metallization, at least one elongated bus wire. The bus wire comprises: a light reflecting surface and an obverse, base surface; and the reflecting surface comprises a plurality of inclined faces arranged in a pattern comprising grooves that extend substantially parallel the dimension of elongation of the bus wire. Overlying the at least one bus wire and the absorber, are an encapsulant and a light transparent cover, the cover having an external surface relative to which at least two of the faces are inclined at face angles. The inclined faces, the cover and the absorber all are arranged so that incident light that strikes the bus wire along a line perpendicular to the cover external surface reflects from the bus wire to an interface of the cover and an outside environment, undergoes TIR to the absorber. Once provided, the method of installing further comprises aligning the photovoltaic device so that the grooves are substantially horizontal at the location.

A related invention to those discussed above is a method of making a photovoltaic device, comprising the steps of: providing a light absorber contacted by a metallization; providing at least one preformed elongated, bus wire, comprising: a light reflecting surface and an obverse base surface; the reflecting surface comprising a plurality of faces inclined relative to each other; and placing the preformed bus wire on the absorber contacting the metallization. The faces and the absorber are arranged so that, when an encapsulant, and a light transparent cover having an external surface, are placed over the bus wire and the absorber so that at least two faces are inclined at face angles relative to the cover external surface, light that strikes the bus wire along a line that is perpendicular to the cover external surface, reflects from the bus wire to the interface of the cover and an outside environment, and undergoes TIR to the absorber.

A final related embodiment of an invention hereof is a photovoltaic device comprising a light absorber having a metallization contacted thereto; and at least one preformed elongated bus wire, contacting the metallization, the bus wire comprising: a light reflecting surface and an obverse, base surface, the reflecting surface comprising a plurality of inclined faces. The faces and the absorber are all arranged so when an encapsulant, and a light transparent cover having an external surface, overlie the at least one bus wire and the absorber, with the faces inclined at face angles relative to a line perpendicular to the cover external surface, light that strikes the bus wire faces along a line that is perpendicular to the cover external surface, reflects from the faces to an interface of the cover and an outside environment, undergoing TIR to the absorber.

Many techniques and aspects of the inventions have been described herein. The person skilled in the art will understand that many of these techniques can be used with other disclosed techniques, even if they have not been specifically described in use together. For instance, any of the various shapes for faces or grooves can be used, either alone, or in combination. Any of the techniques for forming the shaped faces, such as rolling, stamping, embossing, drawing and extruding can be used to form any shape formable thereby. The surfaces of the faces may be specular, or not, coated or not.

This disclosure describes and discloses more than one invention. The inventions are set forth in the claims of this and related documents, not only as filed, but also as developed during prosecution of any patent application based on this disclosure. The inventors intend to claim all of the various inventions to the limits permitted by the prior art, as it is subsequently determined to be. No feature described herein is essential to each invention disclosed herein. Thus, the inventors intend that no features described herein, but not claimed in any particular claim of any patent based on this disclosure, should be incorporated into any such claim.

Some assemblies of hardware, or groups of steps, are referred to herein as an invention. However, this is not an admission that any such assemblies or groups are necessarily patentably distinct inventions, particularly as contemplated by laws and regulations regarding the number of inventions that will be examined in one patent application, or unity of invention. It is intended to be a short way of saying an embodiment of an invention.

An abstract is submitted herewith. It is emphasized that this abstract is being provided to comply with the rule requiring an abstract that will allow examiners and other searchers to quickly ascertain the subject matter of the technical disclosure. It is submitted with the understanding that it will not be used to interpret or limit the scope or meaning of the claims, as promised by the Patent Office's rule.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

What is claimed is:

1. A method of making a photovoltaic device, comprising the steps of:
a. providing a light absorber contacted by a metallization;
b. providing at least one preformed elongated, bus wire, comprising:
i. a light reflecting surface and an obverse base surface;
ii. the reflecting surface comprising a plurality of faces inclined relative to each other;
c. placing the bus wire on the absorber, contacting the metallization; and
d. placing an encapsulant and a light transparent cover over the bus wire and the absorber, the cover having an external surface, so that at least two of the faces are inclined at face angles relative to the external surface of the cover;
the faces, the cover and the absorber being arranged and the indices of refraction of the cover and the encapsulant being chosen so that light that strikes the bus wire along a line that is perpendicular to the cover external surface, reflects from the bus wire to an interface of the cover and an outside environment and undergoes Total Internal Reflection (TIR) to the absorber.

2. The method of making a photovoltaic device of claim 1, the faces, and the absorber being arranged so that at least 20% of the light that strikes the bus wire along the line that is perpendicular to the cover external surface undergoes TIR to the absorber.

3. The method of claim 1, the faces and the absorber being arranged so that at least 50% of the light that strikes the bus wire as omnidirectional illumination undergoes TIR to the absorber.

4. The method of claim 1, the faces comprising non-planar surfaces.

5. The method of claim 1, the faces comprising a plurality of pairs of adjacent faces, each pair meeting at a crest.

6. The method of claim 1, the faces comprising two sets of congruent surfaces inclined at face angles relative to a line that is perpendicular to the cover external surface.

7. The method of claim 1, the face angles being of different magnitudes.

8. The method of claim 1, the face angles being of substantially equal magnitude.

9. The method of claim 6, one set of surfaces comprising faces with positive face angles, the other of the two sets comprising faces with negative face angles, with a positive angle face meeting a negative angle face at a crest.

10. The method of claim 1, the inclined faces, the cover and the absorber being arranged such that light that strikes the bus wire along a line perpendicular to the cover external surface reflects and strikes the external surface of the cover at an internal interface angle of greater than about 42° relative to a line perpendicular to the cover external surface.

11. The method of claim 1, the faces arranged in a pattern comprising grooves that extend substantially parallel to the dimension of elongation of the bus wire.

12. The method of claim 1, the face angles being between 50° and 70°.

13. The method of claim 1, the face angles being between 55° and 65°.

14. The method of claim 1, the faces arranged in a pattern comprising parallel grooves that are inclined relative to the dimension of elongation of the bus wire.

15. The method of claim 1, the faces arranged in a pattern comprising a plurality of V-shaped grooves.

16. The method of claim 1 the faces arranged in a pattern comprising a plurality of pyramids.

17. The method of claim 1, the faces arranged in a pattern comprising a plurality of pairs of V-shaped grooves, at least one pair forming a chevron.

18. The method of claim 1, the bus wire comprising a rolled surface.

19. The method of claim 1, the bus wire comprising a stamped surface.

20. The method of claim 1, the bus wire comprising an extruded surface.

21. The method of claim 1, the bus wire comprising a drawn surface.

22. The method of claim 1, the bus wire light reflecting surface comprising a surface to which faces have been applied before contacting the bus wire to the absorber.

23. The method of claim 1, the step of contacting the bus wire to the metallization comprising soldering.

24. The method of claim 5, adjacent crests between the plurality of faces being separated at a spacing of between approximately 10 microns and 300 microns.

25. The method of claim 5, adjacent crests between the plurality of faces being separated at a spacing of between approximately 50 microns and 200 microns.

26. The method of claim 1, the plurality of faces being sized at between approximately 25 microns and 100 microns.

27. The method of claim 1, further where the metallization comprises a bus bar, the step of placing the bus wire comprising placing it so that it contacts and at least partially overlays the bus bar.

28. The method of claim 1, further where the metallization comprises a network of gridlines, the step of placing the bus wire comprising placing it so that it contacts and overlies at least one gridline.

29. The method of claim 1, the photovoltaic device comprising a solar cell.

30. The method of claim 1, the faces of the bus wire comprising specular surfaces.

31. The method of claim 1, the reflecting surface comprising silver.

32. The method of claim 31, the silver comprising a plating.

33. The method of claim 1, the step of placing the bus wire on the absorber being conducted after a step of forming the faces on the bus wire reflecting surface.

34. The method of claim 1, further comprising the steps of:
a. providing a second photovoltaic device of claim 201; and
b. electrically coupling the second photovoltaic device to the first photovoltaic device by establishing electrical continuity from the bus wire of the first photovoltaic device to the second photovoltaic device, thereby forming a string of photovoltaic devices.

35. The method of claim 34, further comprising the steps of:
a. providing a third photovoltaic device of claim 1;
b. electrically coupling the third photovoltaic device to the first string of photovoltaic devices by establishing electrical continuity from a bus wire of the first string of photovoltaic devices to the third photovoltaic device.

36. A method of making a photovoltaic device, comprising the steps of:
a. providing a light absorber contacted by a metallization;
b. providing at least one preformed elongated, bus wire, comprising:
i. a light reflecting surface and an obverse base surface;
ii. the reflecting surface comprising a plurality of faces inclined relative to each other;
c. placing the bus wire on the light absorbing device contacting the metallization;
d. placing an encapsulant and a light transparent cover over the bus wire and the absorber, the cover having an external surface, so that the faces are inclined, each at a face angle relative to the external surface of the cover;
the faces, the cover and the absorber being arranged and the indices of refraction of the cover and the encapsulant being chosen so that substantially all of the light that strikes the cover external surface at any external interface angle less than 27 degrees relative to the perpendicular to the cover surface, reflects from the bus wire to an interface of the cover and an outside environment and undergoes Total Internal Reflection (TIR) to the absorber.

37. A method of making a photovoltaic device, comprising the steps of:
a. providing a light absorber contacted by a metallization;
b. providing at least one preformed elongated, bus wire, comprising:
i. a light reflecting surface and an obverse base surface;
ii. the reflecting surface comprising a plurality of faces inclined relative to each other;
c. placing the bus wire on the light absorbing device contacting the metallization;
d. placing an encapsulant and a light transparent cover over the bus wire and the absorber, the cover having an external surface, so that the faces are inclined, each at a face angle relative to the external surface of the cover;
the faces, the cover and the absorber being arranged and the indices of refraction of the cover and the encapsulant being chosen so that 50% of the light that strikes the bus wire as omnidirectional illumination reflects from the bus wire to an interface of the cover and an outside environment and undergoes Total Internal Reflection (TIR) to the absorber.

38. A photovoltaic device comprising:
a. a light absorber having a metallization contacted thereto;
b. contacting the metallization, at least one preformed elongated bus wire, comprising:
i. a light reflecting surface and an obverse, base surface;
ii. the reflecting surface comprising a plurality of inclined faces; and
c. overlying the at least one bus wire and the absorber, an encapsulant and a light transparent cover, the cover having an external surface relative to which at least two faces are inclined at face angles;
the inclined faces, the cover and the absorber all arranged so that light that strikes the conductor along a line that is perpendicular to the cover external surface, reflects from the bus wire to an interface of the cover and an outside environment, undergoing Total Internal Reflection (TIR) to the absorber.

39. The photovoltaic device of claim 38, the faces, and the absorber being arranged so that at least 20% of the light that strikes the bus wire along the line that is perpendicular to the cover external surface undergoes TIR to the absorber.

40. The photovoltaic device of claim 38, the faces and the absorber being arranged so that at least 50% of the light that strikes the bus wire as omnidirectional illumination undergoes TIR to the absorber.

41. The photovoltaic device of claim 38, the faces comprising non-planar surfaces.

42. The photovoltaic device of claim 38, the faces comprising a plurality of pairs of adjacent faces, each pair meeting at a crest.

43. The photovoltaic device of claim 38, the faces comprising two sets of congruent faces inclined at face angles relative to a line that is perpendicular to the cover external surface.

44. The photovoltaic device of claim 38, the face angles being of different magnitudes.

45. The photovoltaic device of claim 38, the face angles being of substantially equal magnitude.

46. The photovoltaic device of claim 43, one set of surfaces comprising faces with positive face angles, the other of the two sets comprising faces with negative face angles, with a positive angle face meeting a negative angle face at a crest.

47. The photovoltaic device of claim 38, the inclined faces, the cover and the absorber being arranged and having indices of refraction such that light that strikes an inclined face along a line that is perpendicular to the cover external surface, reflects and strikes the interface between the cover and the external environment at an internal interface angle of greater than about 42° relative to a line perpendicular to the cover external surface.

48. The photovoltaic device of claim 38, the faces arranged in a pattern comprising grooves that extend substantially parallel the dimension of elongation of the bus wire.

49. The photovoltaic device of claim 38, the face angles being between 50° and 70°.

50. The photovoltaic device of claim 38, the face angles being between 55° and 65°.

51. The photovoltaic device of claim 38, the faces arranged in a pattern comprising parallel grooves that are inclined relative to the dimension of elongation of the bus wire.

52. The photovoltaic device of claim 38, the faces arranged in a pattern comprising a plurality of V-shaped grooves.

53. The photovoltaic device of claim 38, the faces arranged in a pattern comprising a plurality of pyramids.

54. The photovoltaic device of claim 38, the faces arranged in a pattern comprising a plurality of pairs of v-shaped grooves, at least one pair forming a chevron.

55. The photovoltaic device of claim 38, the bus wire comprising a rolled surface.

56. The photovoltaic device of claim 38, the bus wire comprising a stamped surface.

57. The photovoltaic device of claim 38, the bus wire comprising a drawn surface.

58. The photovoltaic device of claim 38, the bus wire light reflecting surface comprising a surface to which the faces have been applied before contacting the bus wire to the metallization.

59. The photovoltaic device of claim 42, adjacent crests between the plurality of faces being separated at a spacing of between approximately 10 microns and 300 microns.

60. The photovoltaic device of claim 42, adjacent crests between the plurality of faces being separated at a spacing of between approximately 50 microns and 200 microns.

61. The photovoltaic device of claim 38, the plurality of faces being sized at between approximately 25 microns and 100 microns.

62. The photovoltaic device of claim 38, further where the metallization comprises a network of gridlines, the bus wire overlaying at least one gridline.

63. The photovoltaic device of claim 38, further where the metallization comprises a bus bar, the bus wire contacting and overlaying at least part of the bus bar.

64. The photovoltaic device of claim 38, the photovoltaic device comprising a solar cell.

65. The photovoltaic device of claim 38, the bus wire faces comprising specular surfaces.

66. The photovoltaic device of claim 38, the reflecting surface comprising silver.

67. The photovoltaic device of claim 66, the silver comprising a plating.

68. The photovoltaic device of claim 38, the bus wire comprising a preformed bus wire, upon which the faces have been formed before the bus wire is contacted to the metallization.

69. The photovoltaic device of claim 38, further comprising:
a. a second photovoltaic device of claim 38, electrically coupled to the photovoltaic device of claim 38; and
b. the second photovoltaic device being coupled to the first photovoltaic device by electrical continuity from the bus wire of the first photovoltaic device to the second photovoltaic device, thereby forming a string of photovoltaic devices.

70. The photovoltaic device of claim 69, further comprising:
a. a third photovoltaic device of claim 38, electrically coupled to the string of photovoltaic devices of claim 69; and
b. the third photovoltaic device being electrically coupled to the first string of photovoltaic devices by electrical continuity from a bus wire of the first string of photovoltaic device to the third photovoltaic device.

71. The photovoltaic device of claim 69, the electrical continuity from the bus wire of the first photovoltaic device to the second photovoltaic device comprising an end portion of the bus wire of at least one of the first and second photovoltaic devices.

72. The photovoltaic device of claim 71, an end portion of the bus wire of at least one of the first and second photovoltaic devices bearing inclined faces.

73. The photovoltaic device of claim 71, an end portion of the bus wire of at least one of the first and second photovoltaic devices being free of inclined faces.

74. A method of forming a buswire comprising the steps of:
a. providing a wire having a first surface and an obverse, base surface that defines a base plane; and
b. forming on the first surface, a plurality of specular light reflecting faces that are inclined at face angles having magnitudes between 50° and 70° relative to a line that is perpendicular to the base plane.

75. The method of forming a bus wire of claim 74, adjacent faces of the plurality of faces meeting at crests that are separated at a spacing of between approximately fifty microns and two hundred microns.

76. The method of forming a bus wire of claim 74, the faces arranged in a pattern comprising substantially parallel grooves that extend along the dimension of elongation of the conductor.

77. The method of forming a bus wire of claim 74, the step of forming faces comprising rolling a tool along the wire.

78. A bus wire comprising: a free-standing elongated electrical conductor having a light reflecting surface and an obverse, base surface which defines a base plane, the reflecting surface comprising a plurality of specular faces that are inclined, at face angles having magnitudes between 50° and 70° relative to a line that is perpendicular to the base plane.

79. The bus wire of claim 78, adjacent faces of the plurality of faces meeting at crests that are separated at a spacing of between approximately fifty microns and two hundred microns.

80. The bus wire of claim 78, the faces arranged in a pattern comprising substantially parallel grooves that extend along the dimension of elongation of the conductor.

81. The bus wire of claim 78, the bus wire comprising a rolled surface.

82. A method of making a buswire for use with a photovoltaic device, the photovoltaic device having a light absorber contacted by a metallization, the method of making a buswire comprising the steps of:
a. providing at least one elongated wire, comprising a first surface and an obverse base surface; and
b. forming on the first surface, a plurality of specular light reflecting faces inclined relative to each other;
the faces being arranged so that, when the formed bus wire is placed on the absorber with the obverse surface contacting the metallization, and when an encapsulant, and a light transparent cover having an external surface are placed over the bus wire and the absorber so that at least two faces are inclined at face angles relative to the cover external surface, light that strikes the bus wire along a line that is perpendicular to the cover external surface, reflects from the bus wire to the interface of the cover and an outside environment, and undergoes Total Internal Reflection (TIR) to the absorber.

83. The method of claim 82, the inclined faces, the cover and the absorber being arranged such that light that strikes the bus wire along a line perpendicular to the cover external surface reflects and strikes the external surface of the cover at an internal interface angle of greater than about 42° relative to a line perpendicular to the cover external surface.

84. The method of claim 82, the faces arranged in a pattern comprising grooves that extend substantially parallel the dimension of elongation of the bus wire.

85. The method of claim 82, the face angles being between 55° and 65°.

86. The method of claim 82, the step of forming faces comprising rolling a tool along the wire.

87. The method of claim 82, adjacent faces meeting at crests that are separated at a spacing of between approximately fifty microns and two hundred microns.

88. A bus wire for use with a photovoltaic device having a light absorber, an encapsulant and a light transparent cover having an external surface, the bus wire comprising:
a. a free-standing elongated electrical conductor having a light reflecting surface and an obverse, base surface;
b. the reflecting surface comprising a plurality of specular faces that are inclined, relative to each other, such that when the base surface contacts an absorber, and an encapsulant and a cover overlie the conductor and the absorber, light that strikes the conductor along a line perpendicular to an external surface of the cover reflects from the conductor to an interface of the cover and an outside environment and undergoes Total Internal Reflection (TIR) to the absorber.

89. The bus wire of claim 88, the faces being arranged such that when the absorber and a cover are present, light that strikes the conductor along a line perpendicular to the cover external surface, reflects and strikes the interface between the cover and an external environment at an internal interface angle of greater than about 42° relative to a line perpendicular to the cover external surface.

90. The bus wire of claim 88, the faces arranged in a pattern comprising grooves that extend substantially parallel to the dimension of elongation of the conductor.

91. The bus wire of claim 88, the faces being inclined at face angles relative to a perpendicular to the cover external surface, the face angles being between 55° and 65°.

92. The bus wire of claim 88, the elongated conductor comprising a rolled surface.

93. The bus wire of claim 88, the elongated conductor light reflecting surface comprising a surface to which the faces have been provided before contacting the conductor to any absorber.

94. The bus wire of claim 88, adjacent faces of the plurality of faces meeting at crests that are separated at a spacing of between approximately 50 microns and two hundred microns.

95. A method of installing a photovoltaic device at a geographical location comprising the steps of:
a. providing a photovoltaic device comprising:
i. a light absorber, and a metallization contacted thereto;
ii. contacting the absorber at the metallization, at least one elongated bus wire, comprising:
A. a light reflecting surface and an obverse, base surface; and
B. the reflecting surface comprising a plurality of inclined faces arranged in a pattern comprising grooves that extend substantially parallel the dimension of elongation of the bus wire; and
iii. overlying the at least one bus wire and the absorber, an encapsulant and a light transparent cover, having an external surface relative to which at least two of the faces are inclined at face angles;
iv. the inclined faces, the cover and the absorber all arranged so that incident light that strikes the bus wire along a line perpendicular to the cover external surface reflects from the bus wire to an interface of the cover and an outside environment, undergoing Total Internal Reflection (TIR) to the absorber; and
b. aligning the photovoltaic device, so that the grooves are substantially horizontal at the location.

96. A method of making a photovoltaic device, comprising the steps of:
a. providing a light absorber contacted by a metallization;
b. providing at least one preformed elongated, bus wire, comprising:
i. a light reflecting surface and an obverse base surface;
ii. the reflecting surface comprising a plurality of faces inclined relative to each other;
c. placing the preformed bus wire on the absorber contacting the metallization;
the faces, and the absorber being arranged so that, when an encapsulant, and a light transparent cover having an external surface, are placed over the bus wire and the absorber so that at least two faces are inclined at face angles relative to the cover external surface, light that strikes the bus wire along a line that is perpendicular to the cover external surface, reflects from the bus wire to the interface of the cover and an outside environment, and undergoes TIR to the absorber.

97. The method of making a photovoltaic device of claim 96, the faces, and the absorber being arranged so that at least 20% of light that strikes the bus wire along the line that is perpendicular to the cover external surface undergoes Total Internal Reflection (TIR) to the absorber.

98. A photovoltaic device comprising:
a. a light absorber having a metallization contacted thereto;
b. contacting the metallization, at least one preformed elongated bus wire, comprising:
i. a light reflecting surface and an obverse, base surface;
ii. the reflecting surface comprising a plurality of inclined faces; and
the faces and the absorber all arranged so when an encapsulant, and a light transparent cover having an external surface, overlie the at least one bus wire and the absorber, with the faces inclined at face angles relative to a line perpendicular to the cover external surface, light that strikes the bus wire faces along a line that is perpendicular to the cover external surface, reflects from the faces to an interface of the cover and an outside environment, undergoing Total Internal Reflection (TIR) to the absorber.

99. The photovoltaic device of claim 98, the faces, and the absorber being arranged so that at least 20% of the light that strikes the bus wire along the line that is perpendicular to the cover external surface undergoes TIR to the absorber.
